(19) United States
(12) Patent Application Publication
(10) Pub. No.: US 2026/0343986 A1
(43) Pub. Date: Oct. 29, 2026

(54) NANOSTRUCTURE DEVICE AND METHODS OF FORMING THE SAME

(71) Applicant: Taiwan Semiconductor Manufacturing Co., Ltd., Hsinchu (TW)

(72) Inventors: Tzu-Ging Lin, Kaohsiung City (TW); Yun-Chen Wu, Hsinchu (TW); Jian-Yu Chen, Taipei City (TW)

(21) Appl. No.: 19/732,692

(22) Filed: Jul. 7, 2026

Related U.S. Application Data
(63) Continuation of application No. 18/830,926, filed on Sep. 11, 2024.

(51) Int. Cl. H10D 64/01; H10D 30/01; H10D 30/43; H10D 30/67; H10D 62/10; H10D 62/13; H10D 84/01; H10D 84/03; H10D 84/85

(52) U.S. Cl. CPC H10D 64/017; H10D 30/014; H10D 30/43; H10D 30/6735; H10D 30/6757; H10D 62/115; H10D 62/121; H10D 62/151; H10D 84/017; H10D 84/0188; H10D 84/038; H10D 84/85

(57) ABSTRACT

A method includes forming a fin structure over a substrate; forming first nanostructures and second nanostructures over the fin structure, wherein the first nanostructures are continuous with respective second nanostructures; forming first dielectric dummy regions between ones of the first nanostructures, and second dielectric dummy regions between ones of the second nanostructures; forming first source/drain regions adjacent the first nanostructures and second source/drain regions adjacent the second nanostructures; performing an etching process to remove the first dielectric dummy regions and the second dielectric dummy regions; depositing gate structure layers on the first nanostructures and the second nanostructures; and forming an isolation region between the first nanostructures and the second nanostructures, wherein the isolation region physically separates the first nanostructures from the second nanostructures.

### PRIORITY CLAIM AND CROSS-REFERENCE

This application is a continuation of U.S. patent application Ser. No. 18/830,926, filed on Sep. 11, 2024, which application is hereby incorporated herein by reference.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example of a nanostructure field-effect transistor (nanostructure-FET) in a three-dimensional view, in accordance with some embodiments.

FIGS. 2, 3A, 3B, 4, 5A, 5B, 6A, 6B, 7A, 7B, 8A, 8B, 8C, 8D, 9A, 9B, 10A, 10B, 11A, 11B, 11C, 12A, 12B, 12C, 13A, 13B, 14A, 14B, 14C, 14D, 14E, 15A, 15B, 15C, 15D, 16A, 16B, 16C, 16D, 17A, 17B, 17C, 17D, 18A, 18B, 18C, 18D, 19A, 19B, 19C, 19D, 20, 21A, 21B, 22A, 22B, 22C, 22D, 23A, 23B, 23C, 23D, 24A, 24B, 24C, 24D, 25A, 25B, 25C, 25D, 26A, 26B, 26C, 26D, 27A, 27B, 27C, 27D, 28A, 28B, and 28C illustrate various views of intermediate stages in the manufacturing of nanostructure-FETs, in accordance with some embodiments.

FIGS. 29A, 29B, and 29C illustrate plan views of continuous fin structures, in accordance with some embodiments.

FIGS. 30A, 30B, 30C, and 30D illustrate plan views of fins and isolation regions between fins, in accordance with some embodiments

FIGS. 31A, 31B, 31C, 31D, 31E, 31F, and 31G illustrate plan views of continuous fin structures, in accordance with some embodiments.

FIGS. 32A, 32B, 33A, 33B, 33C, 33D, 34A, 34B, 34C, 34D, 35A, 35B, 35C, 35D, 36A, 36B, 36C, 36D, 37A, 37B, 37C, 37D, 38, and 39 illustrate various views of intermediate stages in the manufacturing of nanostructure-FETs, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments are described below in a particular context, a die comprising nanostructure field-effect transistors (e.g., “nanostructure-FETs” or “nano-FETs”). Various embodiments may be applied, however, to dies comprising other types of transistors (e.g., fin field-effect transistors (FinFETs), planar transistors, stacking transistors, or the like) in lieu of or in combination with the nanostructure-FETs.

According to various embodiments, oxide dummy regions are used to fill regions between channel regions of a nanostructure-FET where the gate structures are subsequently formed. The use of oxide dummy regions allows for more selective etches to be used when removing the oxide dummy regions, which can reduce the risk of etch damage to the channel regions or the source/drain regions. The reduced risk of etch damage allows isolation regions to be more safely formed after formation of the gate structures, which can improve device density and yield.

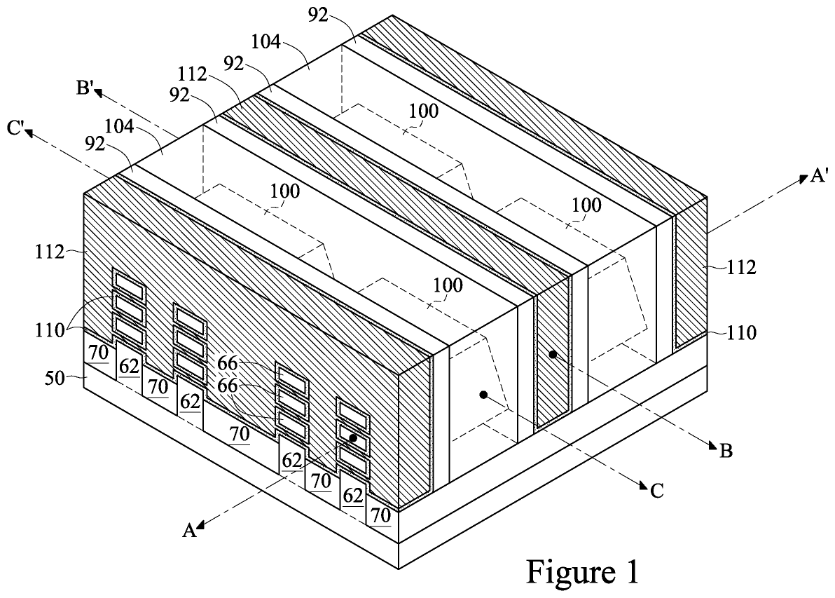

FIG. 1 illustrates an example of nanostructure-FETs (e.g., nanowire FETs, nanosheet FETs, nano-FETs, or the like), gate-all-around (GAA) FETs, or the like) in a three-dimensional view, in accordance with some embodiments. Some features of the nanostructure-FETs may be simplified and/or omitted in FIG. 1 for clarity. The nanostructure-FETs comprise nanostructures 66 (e.g., nanosheets, nanowires, or the like) over fins 62 on a substrate 50 (e.g., a semiconductor substrate), with the nanostructures 66 being semiconductor features that act as channel regions for the nanostructure-FETs. The nanostructures 66 may include p-type nanostructures, n-type nanostructures, or a combination thereof. Isolation regions 70, such as shallow trench isolation (STI) regions, are disposed between adjacent fins 62, which may protrude above and from between neighboring isolation regions 70. The nanostructures 66 are disposed over and between adjacent isolation regions 70. Some portions of the isolation regions 70 may be covered by a protective layer or hard mask layer (not illustrated in FIG. 1). Although the isolation regions 70 are described/illustrated as being separate from the substrate 50, as used herein, the term “substrate” may refer to the semiconductor substrate alone or a combination of the semiconductor substrate and the isolation regions. Additionally, although a bottom portion of the fins 62 are illustrated as being single, continuous materials with the substrate 50, the bottom portions of the fins 62 and/or the substrate 50 may comprise a single material or a plurality of materials. In this context, the fins 62 refer to the portion extending between the neighboring isolation regions 70.

The gate dielectric layers 110 are over top surfaces of the fins 62 and along top surfaces, sidewalls, and bottom surfaces of the nanostructures 66. Gate electrodes 112 are over the gate dielectric layers 110. The gate dielectric layers 110 and gate electrodes 112 may be collectively be called “gate structures” or “gate stacks.” Isolation regions (not illustrated in FIG. 1 but described in greater detail below) may be formed between fins 62 or at the ends of some fins 62. Source/drain regions 100 (e.g., epitaxial source/drain regions 100) are disposed on the fins 62 at opposing sides of the gate dielectric layers 110 and the gate electrodes 112. Source/drain region(s) 100 may refer to a source or a drain, individually or collectively dependent upon the context. An inter-layer dielectric (ILD) 104 is formed over the source/drain regions 100. Contacts (subsequently described) to the source/drain regions 100 will be formed through the ILD 104. The source/drain regions 100 may be shared between various nanostructures 66. For example, adjacent source/drain regions 100 may be electrically connected, such as through coalescing or merging the source/drain regions 100 by epitaxial growth, or through coupling the source/drain regions 100 with a same contact.

FIG. 1 further illustrates reference cross-sections that are used in later figures. Cross-section A-A′ is along a longitudinal axis of a fin 62 of a nanostructure-FET and in a direction of, for example, a current flow between the source/drain regions 100 of the nanostructure-FET. Cross-section B-B′ is perpendicular to cross-section A-A′ and extends along a longitudinal axis of a gate electrode 112. Cross-section C-C′ is parallel to cross-section B-B′ (e.g., is perpendicular to cross-section A-A′) and extends through source/drain regions 100 of the nanostructure-FETs. Subsequent figures refer to these reference cross-sections for clarity.

Some embodiments discussed herein are discussed in the context of nanostructure-FETs formed using a gate-last process. In other embodiments, a gate-first process may be used. Also, some embodiments contemplate aspects used in planar devices, such as planar FETs, or in fin field-effect transistors (FinFETs), in lieu of or in combination with the nanostructure-FETs. For example, FinFETs may include semiconductor fins on a substrate, with the semiconductor fins being semiconductor features which act as channel regions for the FinFETs. Similarly, planar FETs may include a substrate, with planar portions of the substrate being semiconductor features which act as channel regions for the planar FETs. Other FETs or configurations of FETs are possible.

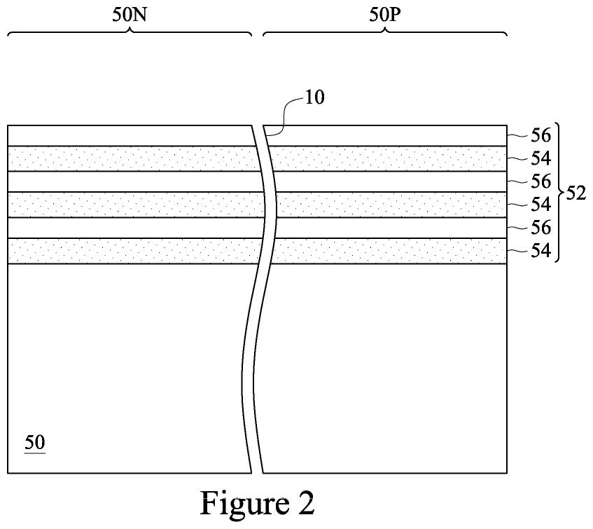

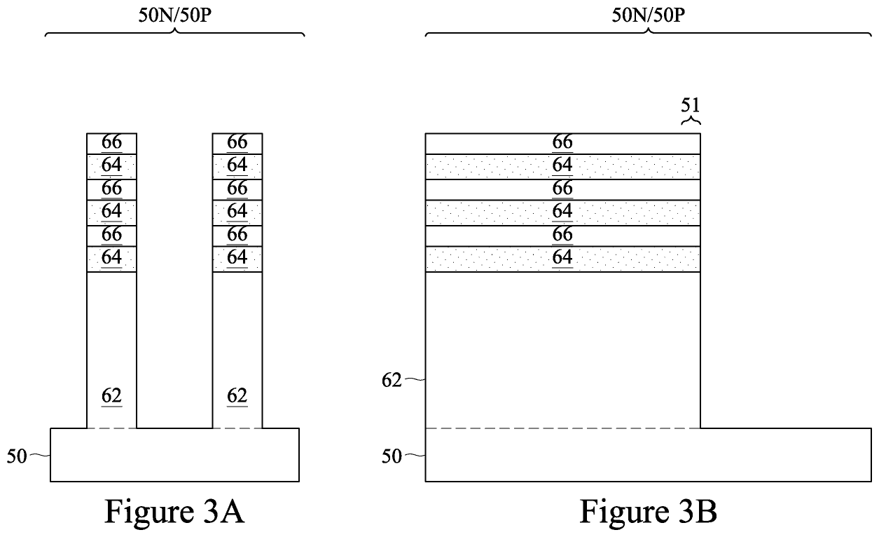

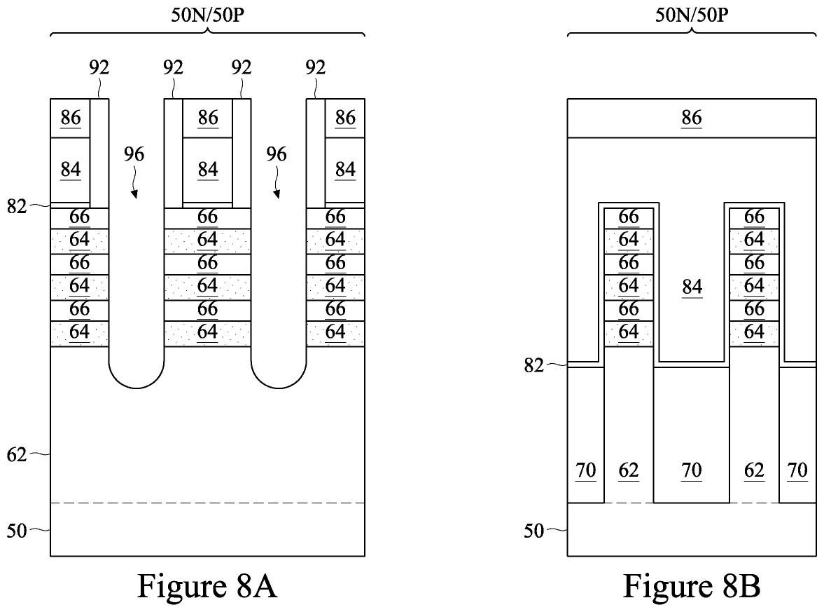

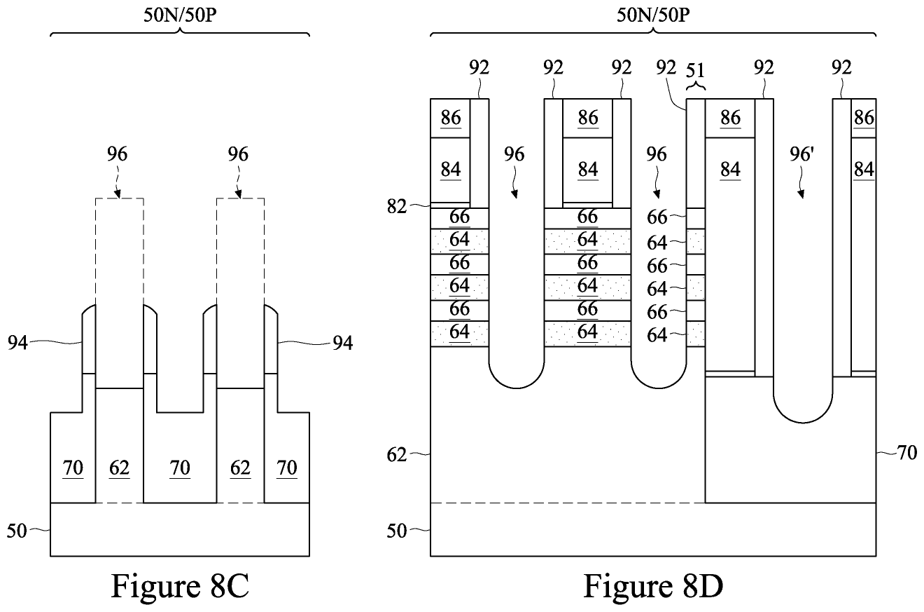

FIGS. 2-28C are views of intermediate stages in the manufacturing of nanostructure-FETs, in accordance with some embodiments. FIGS. 2, 3B, 5B, 6A, 7A, 8A, 8D, 9A, 10A, 11A, 11C, 12A, 12C, 13A, 13B, 14A, 14E, 15A, 15D, 16A, 16D, 17A, 17D, 18A, 18D, 19A, 19D, 20, 21A, 22A, 22D, 23A, 23D, 24A, 24D, 25A, 25D, 26A, 26D, 27A, 27D, and 28A illustrate cross-sectional views along a similar cross-section as reference cross-section A-A′ in FIG. 1. FIGS. 3A, 4, 5A, 6B, 7B, 8B, 9B, 10B, 11B, 12B, 14B, 15B, 16B, 17B, 18B, 19B, 21B, 22B, 23B, 24B, 25B, 26B, 27B, and 28B illustrate cross-sectional views along a similar cross-section as reference cross-section B-B′ in FIG. 1. FIGS. 8C, 14C, 14D, 15C, 16C, 17C, 18C, 19C, 22C, 23C, 24C, 25C, 26C, 27C, and 28C illustrate cross-sectional views along a similar cross-section as reference cross-section C-C′ in FIG. 1.

In FIG. 2, a substrate 50 is provided, in accordance with some embodiments. The substrate 50 may be a semiconductor substrate, such as a bulk semiconductor, a semiconductor-on-insulator (SOI) substrate, or the like, which may be doped (e.g., with a p-type or an n-type dopant) or undoped. The substrate 50 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 50 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof.

The substrate 50 has an n-type region 50N and a p-type region 50P. The n-type region 50N can be for forming n-type devices, such as NMOS transistors, e.g., n-type nanostructure-FETs, and the p-type region 50P can be for forming p-type devices, such as PMOS transistors, e.g., p-type nanostructure-FETs. The n-type region 50N may (or may not) be physically separated (not separately illustrated) from the p-type region 50P, and any number of device features (e.g., other active devices, doped regions, isolation structures, etc.) may be disposed between the n-type region 50N and the p-type region 50P. Although one n-type region 50N and one p-type region 50P are illustrated, any number of n-type regions 50N and p-type regions 50P may be provided. Subsequent figures describe processing steps that may be performed in either the n-type regions 50N or the p-type regions 50P unless otherwise noted.

Further in FIG. 2, a multi-layer stack 52 is formed over the substrate 50, in accordance with some embodiments. The multi-layer stack 52 includes alternating first semiconductor layers 54 and second semiconductor layers 56. The first semiconductor layers 54 are formed of a first semiconductor material, and the second semiconductor layers 56 are formed of a second semiconductor material. The semiconductor materials may each be selected from the candidate semiconductor materials of the substrate 50. In the illustrated embodiment, and as subsequently described in greater detail, the first semiconductor layers 54 will be removed and the second semiconductor layers 56 will patterned to form channel regions for the nanostructure-FETs in both the n-type region 50N and the p-type region 50P. In such embodiments, the channel regions in both the n-type region 50N and the p-type region 50P may have a same material composition (e.g., silicon or another semiconductor material) and be formed simultaneously. The first semiconductor layers 54 are dummy layers that will be removed in subsequent processing to expose top surfaces and bottom surfaces of the second semiconductor layers 56. The first semiconductor material of the first semiconductor layers 54 is a material that has a high etching selectivity from the etching of the second semiconductor layers 56, such as silicon germanium. The second semiconductor material of the second semiconductor layers 56 is a material suitable for both n-type and p-type devices, such as silicon.

In another embodiment (not separately illustrated), the first semiconductor layers 54 will be patterned to form channel regions for nanostructure-FETs in one region (e.g., the p-type region 50P), and the second semiconductor layers 56 will be patterned to form channel regions for nanostructure-FETs in another region (e.g., the n-type region 50N). The first semiconductor material of the first semiconductor layers 54 may be a material suitable for p-type devices, such as silicon germanium (e.g., SiₓGe₁₋ₓ, where x can be in the range of 0 to 1), pure germanium, a III-V compound semiconductor, a II-VI compound semiconductor, or the like. The second semiconductor material of the second semiconductor layers 56 may be a material suitable for n-type devices, such as silicon, silicon carbide, a III-V compound semiconductor, a II-VI compound semiconductor, or the like. The first semiconductor material and the second semiconductor material may have a high etching selectivity from the etching of one another, so that the first semiconductor layers 54 may be removed without significantly removing the second semiconductor layers 56 in the n-type region 50N, and the second semiconductor layers 56 may be removed without significantly removing the first semiconductor layers 54 in the p-type region 50P.

The multi-layer stack 52 is illustrated as including four of the first semiconductor layers 54 and four of the second semiconductor layers 56. It should be appreciated that the multi-layer stack 52 may include any number of the first semiconductor layers 54 and the second semiconductor layers 56. Each of the layers of the multi-layer stack 52 may be grown by a process such as vapor phase epitaxy (VPE) or molecular beam epitaxy (MBE), deposited by a process such as chemical vapor deposition (CVD) or atomic layer deposition (ALD), or the like. In some embodiments, some layers of the multi-layer stack 52 are formed to be thinner than other layers of the multi-layer stack 52. For example, the bottom-most second semiconductor layer 56 (e.g., the second semiconductor layer 56 closest to the substrate 50) may be thinner than overlying second semiconductor layers 56 to improve short channel control in the resulting nanostructure-FETs. Other combinations or variations of layer thicknesses are possible.

In FIGS. 3A-3B, fins 62 are formed in the substrate 50, and first nanostructures 64 and second nanostructures 66 are formed in the multi-layer stack 52, in accordance with some embodiments. The first nanostructures 64 and the second nanostructures 66 may be collectively referred to as the nanostructures 64/66 herein. FIG. 3A illustrates a cross-sectional view along a similar cross-section as reference cross-section B-B′ in FIG. 1, and FIG. 3B illustrates a cross-sectional view along a similar cross-section as reference cross-section A-A′ in FIG. 1. FIG. 3B illustrates an end portion of a fin 62 and overlying nanostructures 64/66, in which the nanostructures 64/66 and fin 62 are removed, e.g., to longitudinally terminate the fin 62 and the nanostructures 64/66. The region at or near the end portion of the fin 62 and nanostructures 64/66 is indicated as the fin end region 51 in FIG. 3B. FIGS. 3A-3B may be in either of the n-type region 50N or the p-type region 50P of the substrate 50 unless specifically discussed.

In some embodiments, the nanostructures 64/66 and the fins 62 may be formed in the multi-layer stack 52 and the substrate 50, respectively, by etching trenches in the multi-layer stack 52 and the substrate 50. The etching may be any acceptable etch process, such as a reactive ion etch (RIE), neutral beam etch (NBE), the like, or a combination thereof. The etching may be anisotropic. Forming the nanostructures 64/66 by etching the multi-layer stack 52 may further define first nanostructures 64 from the first semiconductor layers 54 and define second nanostructures 66 from the second semiconductor layers 56.

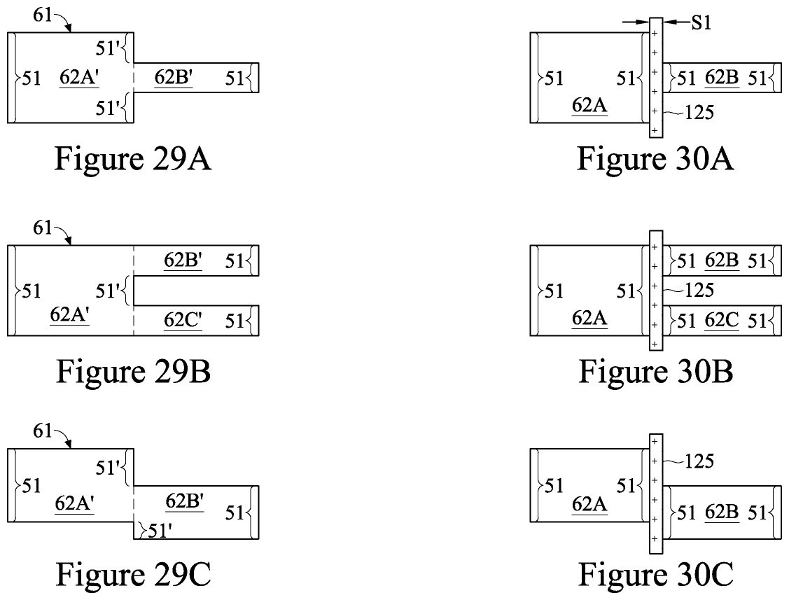

The fins 62 and the nanostructures 64/66 may be patterned by any suitable method. For example, the fins 62 and the nanostructures 64/66 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins 62 and the nanostructures 64/66. Other patterning techniques are possible. In some cases, the fins 62 may be patterned into continuous fin structures 61 that are subsequently separated by isolation regions 125 into separate fins 62, described in greater detail below for FIGS. 29A-31G.

The fins 62 are illustrated as having substantially equal widths in both the n-type region 50N and the p-type region 50P. In some embodiments, a width of the fins 62 in the n-type region 50N may be greater or less than a width of the fins 62 in the p-type region 50P. Further, while each of the fins 62 and the nanostructures 64/66 are illustrated as having a constant width throughout, in other embodiments, the fins 62 and/or the nanostructures 64/66 may have tapered sidewalls such that a width of each of the fins 62 and/or the nanostructures 64/66 continuously increases in a direction towards the substrate 50. In such embodiments, each of the nanostructures 64/66 may have a different width and may be trapezoidal in shape.

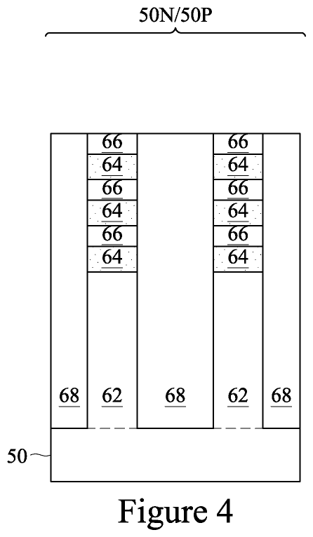

In FIG. 4, an insulation material 68 is formed over the substrate 50 and between adjacent fins 62 and adjacent nanostructures 64/66. The insulation material 68 may be an oxide, such as silicon oxide, a nitride, the like, or a combination thereof, and may be formed by high-density plasma CVD (HDP-CVD), flowable CVD (FCVD), the like, or a combination thereof. Other insulation materials formed by any acceptable process may be used. In some embodiments, the insulation material 68 includes silicon oxide formed by an FCVD process. An annealing process may be performed once the insulation material 68 is formed. Although the insulation material 68 is illustrated as a single layer, some embodiments may utilize multiple layers. For example, in some embodiments a liner (not separately illustrated) may first be formed along a surface of the substrate 50, the fins 62, and the nanostructures 64/66. Thereafter, a fill material, such as one of the previously described insulation materials, may be formed over the liner.

The insulation material 68 may be deposited over the fins 62 and nanostructures 64/66 such that excess insulation material 68 covers the nanostructures 64/66. A removal process is then applied to the insulation material 68 to remove excess insulation material 68 over the nanostructures 64/66. In some embodiments, a planarization process such as a chemical mechanical polish (CMP), an etch-back process, combinations thereof, or the like may be utilized. The planarization process may expose the nanostructures 64/66 such that top surfaces of the nanostructures 64/66 and the insulation material 68 are level after the planarization process is complete.

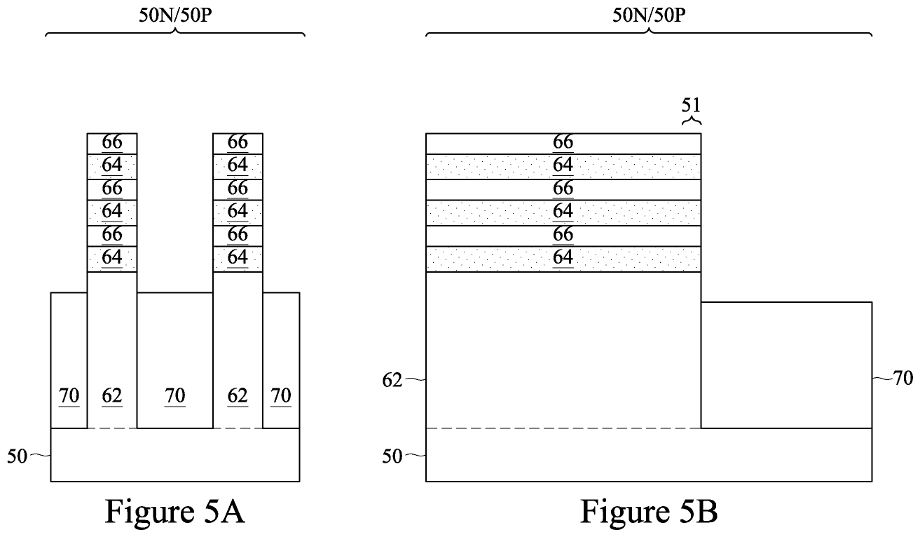

In FIGS. 5A and 5B, the insulation material 68 is recessed to form STI regions 70, in accordance with some embodiments. The STI regions 70 are adjacent to the fins 62, and may be adjacent to end portions of fins 62 (e.g., the fin end regions 51). The insulation material 68 is recessed such that upper portions of fins 62 and/or the nanostructures 64/66 protrude from between neighboring STI regions 70. The upper portions of the fins 62 and/or the nanostructures 64/66 are above the STI regions 70. In some cases, portions of the fins 62 and/or the nanostructures 64/66 may be below a top surface of the STI regions 70. Further, the top surfaces of the STI regions 70 may have a flat surface as illustrated, a convex surface, a concave surface (such as dishing), or a combination thereof. The top surfaces of the STI regions 70 may be formed flat, convex, and/or concave by an appropriate etch. The STI regions 70 may be recessed using an acceptable etching process, such as one that is selective to the material of the insulation material 68 (e.g., etches the material of the insulation material 68 at a faster rate than the materials of the fins 62 and the nanostructures 64/66). For example, an oxide removal using, for example, dilute hydrofluoric (dHF) acid may be used.

The previously described process is just one example of how the fins 62 and the nanostructures 64/66 may be formed. In some embodiments, the fins 62 and/or the nanostructures 64/66 may be formed using a mask and an epitaxial growth process. For example, a dielectric layer can be formed over a top surface of the substrate 50, and trenches can be etched through the dielectric layer to expose the underlying substrate 50. Epitaxial structures can be epitaxially grown in the trenches, and the dielectric layer can be recessed such that the epitaxial structures protrude from the dielectric layer to form the fins 62 and/or the nanostructures 64/66. The epitaxial structures may comprise the previously described alternating semiconductor materials, such as the first semiconductor materials and the second semiconductor materials. In some embodiments in which epitaxial structures are epitaxially grown, the epitaxially grown materials may be in situ doped during growth, which may obviate prior and/or subsequent implantations, although in situ and implantation doping may be used together.

Further in FIGS. 5A-5B, appropriate wells (not separately illustrated) may be formed in the fins 62, the nanostructures 64/66, and/or the STI regions 70. In embodiments with different well types, different implant steps for the n-type region 50N and the p-type region 50P may be achieved using a photoresist or other mask (not separately illustrated). For example, a photoresist may be formed over the fins 62, the nanostructures 64/66, and the STI regions 70 in the n-type region 50N and the p-type region 50P. The photoresist is patterned to expose the p-type region 50P. The photoresist can be formed by using a spin-on technique and can be patterned using acceptable photolithography techniques. Once the photoresist is patterned, an n-type impurity implant is performed in the p-type region 50P, and the photoresist may act as a mask to substantially prevent n-type impurities from being implanted into the n-type region 50N. The n-type impurities may be phosphorus, arsenic, antimony, or the like implanted in the region to a concentration in a range from about 10¹³ atoms/cm³ to about 10¹⁴ atoms/cm³. After the implant, the photoresist is removed, such as by an acceptable ashing process.

Following or prior to the implanting of the p-type region 50P, a photoresist or other mask (not separately illustrated) is formed over the fins 62, the nanostructures 64/66, and the STI regions 70 in the p-type region 50P and the n-type region 50N. The photoresist is patterned to expose the n-type region 50N. The photoresist can be formed by using a spin-on technique and can be patterned using acceptable photolithography techniques. Once the photoresist is patterned, a p-type impurity implant may be performed in the n-type region 50N, and the photoresist may act as a mask to substantially prevent p-type impurities from being implanted into the p-type region 50P. The p-type impurities may be boron, boron fluoride, indium, or the like implanted in the region to a concentration in a range from about 10¹³ atoms/cm³ to about 10¹⁴ atoms/cm³. After the implant, the photoresist may be removed, such as by an acceptable ashing process.

After the implants of the n-type region 50N and the p-type region 50P, an anneal may be performed to repair implant damage and to activate the p-type and/or n-type impurities that were implanted. In some embodiments, the grown materials of epitaxial fins may be in situ doped during growth, which may obviate the implantations, although in situ and implantation doping may be used together.

In other embodiments, a hard mask (not illustrated) may be formed over top surfaces of the STI regions 70 to protect the STI regions 70 during subsequent processing steps. The hard mask may be formed, for example, by first depositing a hard mask material over the nanostructures 64/66, fins 62, and STI regions 70. The hard mask material may be conformally deposited as a continuous layer, in some cases. Then, the hard mask material is removed from top surfaces and sidewalls of the nanostructures 64/66 and fins 62 using an etching process, with the remaining portions on the STI regions 70 forming the hard mask. The upper portions of the hard mask material may be removed using an acceptable etch process, such as a dry etch, a wet etch, or a combination thereof. The hard mask material may comprise one or more materials that have a high etching selectivity from the etching of the materials of the STI regions 70 and/or the nanostructures 64/66. For example, the hard mask material may comprise a nitride, such as silicon nitride, silicon oxynitride, silicon carbonitride, silicon oxycarbonitride, a combination thereof, or the like. In some cases, the hard mask material comprises an oxide, such as hafnium oxide, zirconium oxide, or the like. Other materials are possible, and the hard mask material may comprise multiple layers of different materials, in some cases. The hard mask material may be deposited using a suitable process, such as CVD, plasma-enhanced CVD (PECVD), ALD, or the like.

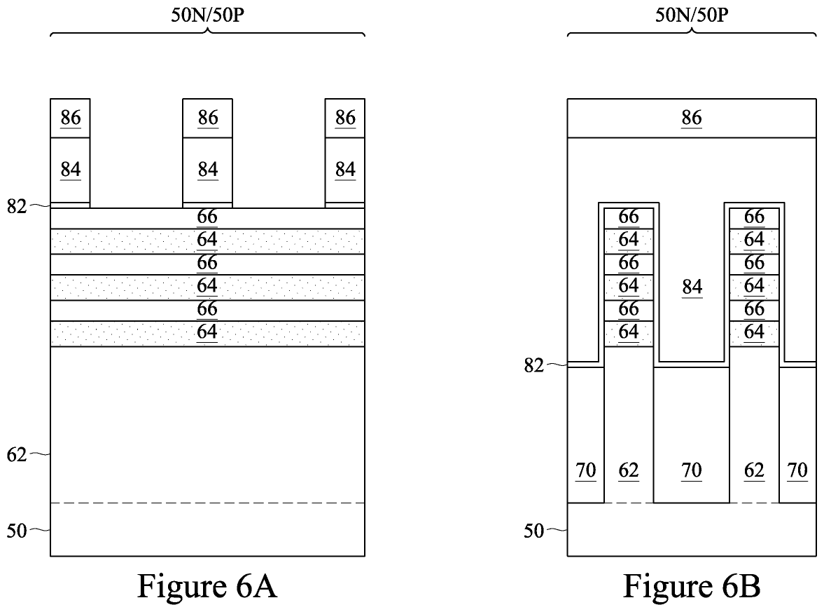

In FIGS. 6A-6B, dummy dielectrics 82, dummy gates 84, and masks 86 are formed over and along sidewalls of the fins 62 and/or the nanostructures 64/66, in accordance with some embodiments. In some embodiments, a dummy dielectric layer is formed on the fins 62 and/or the nanostructures 64/66. The dummy dielectric layer may be formed of silicon oxide, silicon nitride, a combination thereof, or the like, which may be deposited or thermally grown according to acceptable techniques. A dummy gate layer is formed over the dummy dielectric layer, and a mask layer is formed over the dummy gate layer. The dummy gate layer may be deposited over the dummy dielectric layer and then planarized, such as by a CMP process or the like. The dummy gate layer may be formed of a conductive or non-conductive material and may be selected from a group including amorphous silicon, polycrystalline-silicon (polysilicon), polycrystalline silicon-germanium (poly-SiGe), metallic nitrides, metallic silicides, metallic oxides, and metals. The material of the dummy gate layer may be deposited by CVD, physical vapor deposition (PVD), sputter deposition, or another suitable technique. The dummy gate layer may be formed of other materials that have a high etching selectivity from the etching of insulation materials, e.g., the STI regions 70 and/or the dummy dielectric layer. The mask layer may be deposited over the dummy gate layer. The mask layer may be formed of a dielectric material such as silicon nitride, silicon oxynitride, or the like.

Subsequently, the mask layer is patterned using acceptable photolithography and etching techniques to form masks 86. The pattern of the masks 86 then may be transferred to the dummy gate layer and to the dummy dielectric layer to form dummy gates 84 and dummy dielectrics 82, respectively. The dummy gates 84 cover respective channel regions of the nanostructures 64/66. The pattern of the masks 86 may be used to physically separate each of the dummy gates 84 from adjacent dummy gates 84. The dummy gates 84 may also have a lengthwise direction substantially perpendicular to the lengthwise (e.g., longitudinal) direction of respective fins 62. The masks 86 can optionally be removed after patterning, such as by any acceptable etching technique. In this example, a single dummy gate layer and a single mask layer are formed across the n-type region 50N and the p-type region 50P. In the illustrated embodiment, the dummy dielectric layer covers the STI regions 70, such that the dummy dielectrics 82 extends between the dummy gates 84 and the STI regions 70. In another embodiment, the dummy dielectrics 82 covers only the fins 62 and/or the nanostructures 64/66.

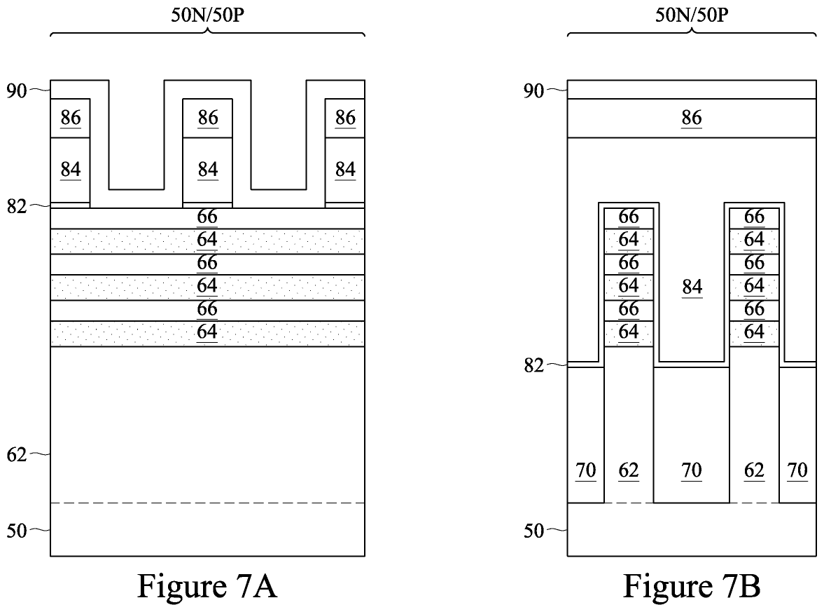

In FIGS. 7A-7B, a spacer layer 90 is conformally formed over the structure, in accordance with some embodiments. The spacer layer 90 is formed over the nanostructures 64/66 and the STI regions 70. The spacer layer 90 is also formed on exposed sidewalls of the masks 86 (if present), the dummy gates 84, the dummy dielectrics 82, the nanostructures 64/66, and/or the fins 62. The spacer layer 90 may be formed of one or more dielectric material(s). FIGS. 7A-7B show a spacer layer 90 formed of a single layer of dielectric material, but in other embodiments the spacer layer 90 may be formed of two or more layers of dielectric materials. Acceptable dielectric materials may include silicon oxide, silicon nitride, silicon oxynitride, silicon oxycarbonitride, or the like, which may be formed by a deposition process such as chemical vapor deposition (CVD), atomic layer deposition (ALD), or the like. Other insulation materials formed by any acceptable process may be used. The spacer layer 90 is subsequently etched to form spacers.

In FIGS. 8A-8D, the spacer layer 90 is patterned to form gate spacers 92 and fin spacers 94. FIG. 8D illustrates an end portion of a fin 62 including a fin end region 51, similar to that shown in FIG. 3B. Any acceptable etch process, such as a dry etch, a wet etch, the like, or a combination thereof, may be performed to pattern the spacer layer 90. The etching may be anisotropic. The spacer layer 90, when etched, has portions left on the sidewalls of the dummy gates 84 (thus forming the gate spacers 92) and has portions left on the sidewalls of the fins 62 and/or the nanostructures 64/66 (thus forming the fin spacers 94). After etching, the fin spacers 94 and/or the gate spacers 92 can have straight sidewalls or can have curved sidewalls. In some embodiments, the STI regions 70 may also be etched when patterning the spacer layer 90. For example, the etching may recess portions the STI regions 70 between fins 62 and/or between gate spacers 92. The gate spacers 92 and/or the fin spacers 94 can have straight sidewalls (as illustrated) or can have curved sidewalls (not separately illustrated).

Further, implants for lightly doped source/drain (LDD) regions (not separately illustrated) may be performed. In embodiments with different device types, similar to the implants for the previously described wells, a mask, such as a photoresist, may be formed over the n-type region 50N, while exposing the p-type region 50P, and appropriate type (e.g., p-type) impurities may be implanted into the fins 62 and the nanostructures 64/66 exposed in the p-type region 50P. The mask may then be removed. Subsequently, a mask, such as a photoresist, may be formed over the p-type region 50P while exposing the n-type region 50N, and appropriate type impurities (e.g., n-type) may be implanted into the fins 62 and the nanostructures 64/66 exposed in the n-type region 50N. The mask may then be removed. The n-type impurities may be the any of the n-type impurities previously discussed, and the p-type impurities may be the any of the p-type impurities previously discussed. The lightly doped source/drain regions may have a concentration of impurities in a range from about 10¹⁵ atoms/cm³ to about 10¹⁹ atoms/cm³. An anneal may be used to repair implant damage and to activate the implanted impurities.

It is noted that the previous disclosure generally describes a process of forming spacers and LDD regions. Other processes and sequences may be used. For example, fewer or additional spacers may be utilized, different sequence of steps may be utilized, additional spacers may be formed and removed, and/or the like. Furthermore, the n-type devices and the p-type devices may be formed using different structures and steps.

Still referring to FIGS. 8A-8D, source/drain recesses 96 are patterned in the fins 62, the nanostructures 64/66, and the substrate 50, in accordance with some embodiments. Epitaxial source/drain regions are subsequently formed in the source/drain recesses 96. The source/drain recesses 96 may extend through the nanostructures 64/66 and into the substrate 50. In some embodiments, the fins 62 may be etched such that bottom surfaces of the source/drain recesses 96 are lower than the top surfaces of the STI regions 70, as shown in FIG. 8C. In other embodiments, the bottom surfaces of the source/drain recesses 96 are about level with or higher than top surfaces of the STI regions 70. The source/drain recesses 96 may be formed by etching the fins 62, the nanostructures 64/66, and the substrate 50 using anisotropic etching processes, such as RIE, NBE, or the like. In some embodiments, the gate spacers 92 and the dummy gates 84 mask portions of the fins 62, the nanostructures 64/66, the STI regions 70, and/or the substrate 50 during the etching processes used to form the source/drain recesses 96. A single etch process or multiple etch processes may be used to etch each layer of the nanostructures 64/66 and/or the fins 62. Timed etch processes may be used to stop the etching of the source/drain recesses 96 after the source/drain recesses 96 reach a desired depth. The etching may etch the STI regions 70, which may form recesses 96′ that extend into the STI regions 70 between gate spacers 92. In other embodiments, the STI regions 70 are not etched. For embodiments in which a hard mask is formed over the STI regions 70, the etching may stop on the hard mask, thin the hard mask, or remove the hard mask, depending on the particulars of the etching process used.

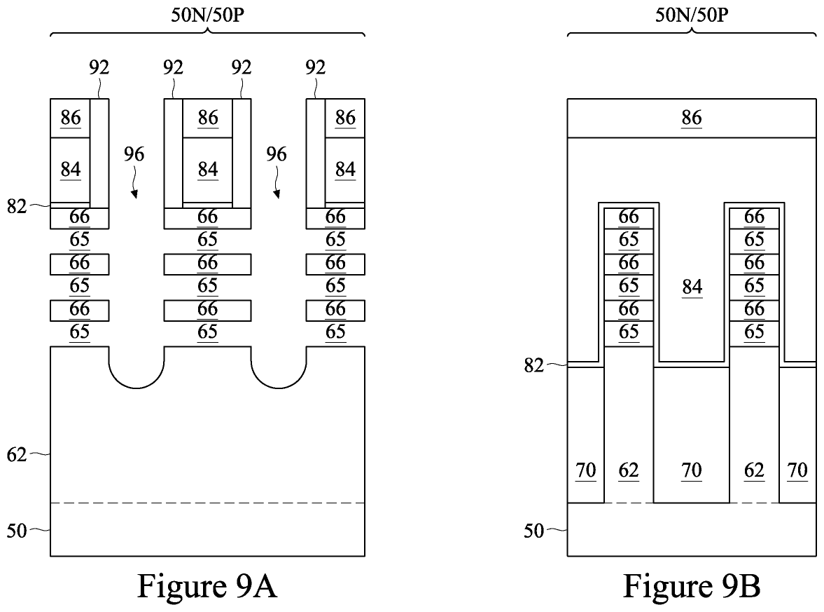

In FIGS. 9A-9B, the remaining portions of the first nanostructures 64 are then removed to form openings 65 in regions between the second nanostructures 66. The remaining portions of the first nanostructures 64 may be removed using an etch process that is performed through the source/drain recesses 96. The etch process may include any acceptable etch process that selectively etches the material of the first nanostructures 64 at a faster rate than the material of the second nanostructures 66 and the fins 62. The etch process may include a wet etch process and/or a dry etch process, and the etching may isotropic. For example, when the first nanostructures 64 are formed of e.g., silicon germanium and the second nanostructures 66 are formed of e.g., silicon or silicon carbide, the etch process may be a wet etch using tetramethylammonium hydroxide (TMAH), ammonium hydroxide (NH₄OH), or the like. In other embodiments, the etch process may be a dry etch using fluorine (F₂), ammonia (NH₃), hydrofluoric acid (HF), chlorine trifluoride (ClF₃), XeF₃, or the like. In some embodiments, a trim process (not illustrated) is performed to decrease the thicknesses of the exposed portions of the second nanostructures 66 and expand the openings 65. Hereinafter, the second nanostructures 66 may be referred to as nanostructures 66, and the collections of vertically adjacent nanostructures 66 over each fin 62 may be referred to as “stacks” of nanostructures 66.

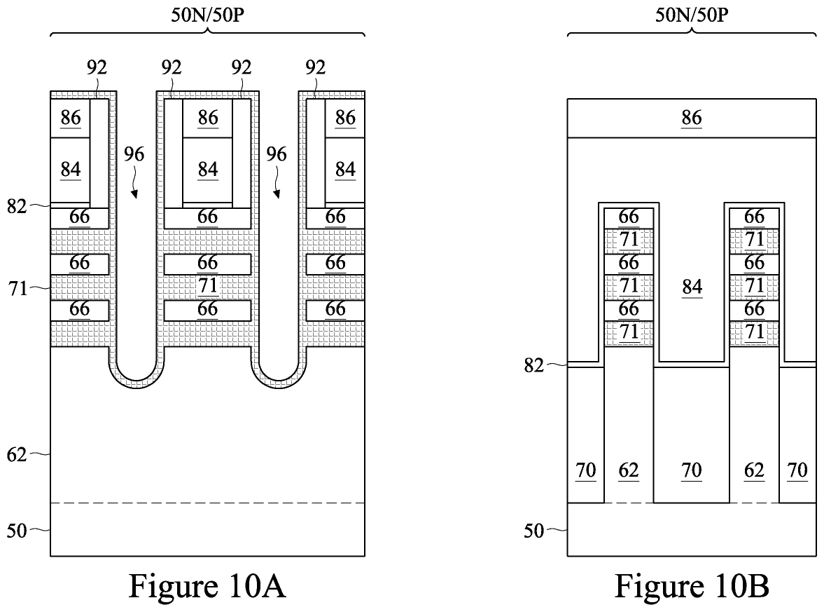

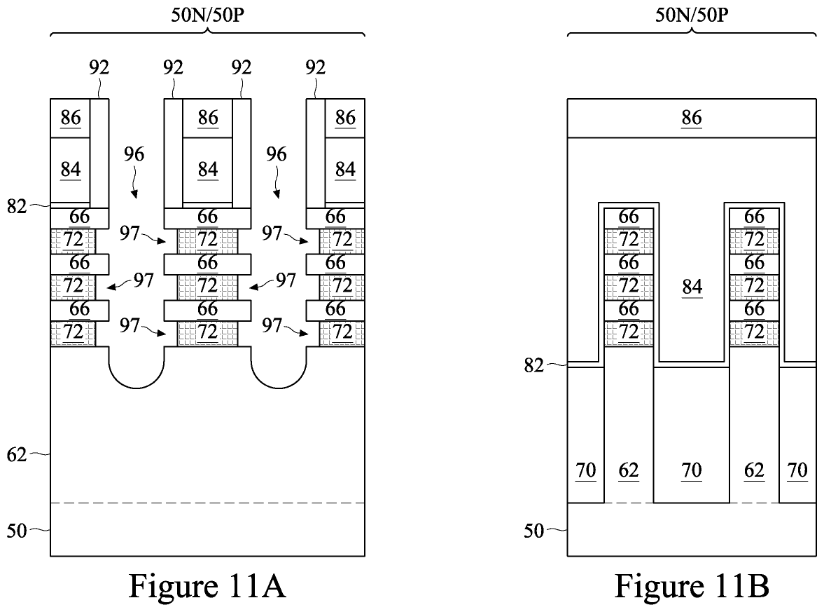

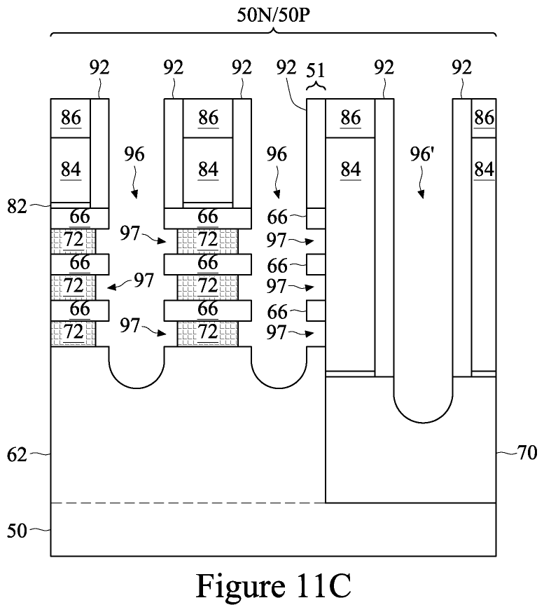

In FIGS. 10A-11C, the first nanostructures 64 are replaced with a dummy material 71 to form dummy regions 72, in accordance with some embodiments. In some cases, the dummy material 71 may be considered a sacrificial material or a sacrificial oxide. In some cases, the dummy regions 72 may be considered sacrificial regions, dielectric dummy regions, dummy nanostructures, dummy gate regions, or disposable oxide interposers (DOI). Replacing the first nanostructures 64 with dummy regions 72 may provide advantages. For example, in subsequent source/drain formation steps, one or more high temperature processes may be performed to, for example, activate the dopants in the source/drain regions. When the material of the first nanostructures 64 (e.g., silicon germanium or the like) is exposed to high temperatures, germanium intermixing and increased roughness at interfaces between the nanostructures 64 and 66 may result. Such manufacturing defects may degrade the performance of the resulting transistor devices. For example, when germanium diffuses into the second nanostructures 66, germanium residue may remain in channel regions of the resulting transistor devices, which negatively affects the performance of the channel regions. Additionally, the intermixing may result in etching selective to either the first nanostructures 64 or the second nanostructures 66 to be less effective and less defined. This can result in, for example, portions of the second nanostructures 66 being undesirably removed, reducing yield and/or causing performance degradation. By replacing the first nanostructures 64 with an insulating material (e.g., the dummy material 71) prior to the high temperature processes (e.g., source/drain annealing), manufacturing defects can be reduced and device performance can be improved (e.g., increased current drive, reduced capacitance, and improved short channel effect). Additionally, the selectivity of etching between the dummy material 71 and the material of the second nanostructures 66 may be greater, allowing for improved etching definition and less unwanted etching of the second nanostructures 66.

In FIGS. 10A-10B, a dummy material 71 is deposited in the recesses 96 and in the openings 65, in accordance with some embodiments. The dummy material 71 may be deposited by a conformal deposition process, such as CVD, ALD, or the like. The dummy material 71 may comprise an insulating material such as silicon oxide or the like that can be selectively etched from the nanostructures 66 and the fins 62. As shown in FIGS. 10A-10B, the dummy material 71 may fill or overfill the openings 65 and may cover sidewalls of the nanostructures 66. The dummy material 71 may cover top surfaces of the fins 62. In some embodiments, the dummy material 71 does not completely fill the source/drain recesses 96.

In FIGS. 11A-11C, the dummy material 71 may then be etched to form the dummy regions 72, in accordance with some embodiments. The etching may be isotropic or anisotropic. For example, the dummy material 71 may be etched using a wet etch process, such as diluted HF (dHF) or the like. In some embodiments, the etching is performed until sidewalls of the dummy material 71 are recessed past sidewalls of the nanostructures 66, forming sidewall recesses 97. Accordingly, the dummy regions 72 may have a width that is smaller than a width of the nanostructures 66. In some cases, the sidewall recesses 97 may be considered part of the source/drain recesses 96. Although sidewalls of the dummy regions 72 within the sidewall recesses 97 are illustrated as being flat, the sidewalls may be concave or convex. FIG. 11C illustrates the dummy material 71 being completely removed from the sidewall recesses 97 in the fin end region 51, exposing the dummy gate 84 adjacent to the fin end region 51. In other embodiments, portions of the dummy material 71 may remain in the sidewall recesses 97 in the fin end region 51 after the etching.

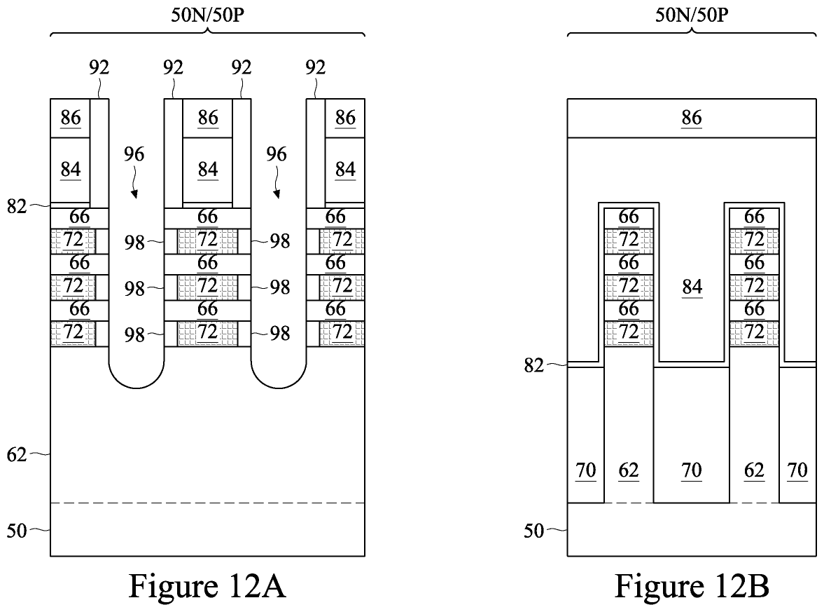

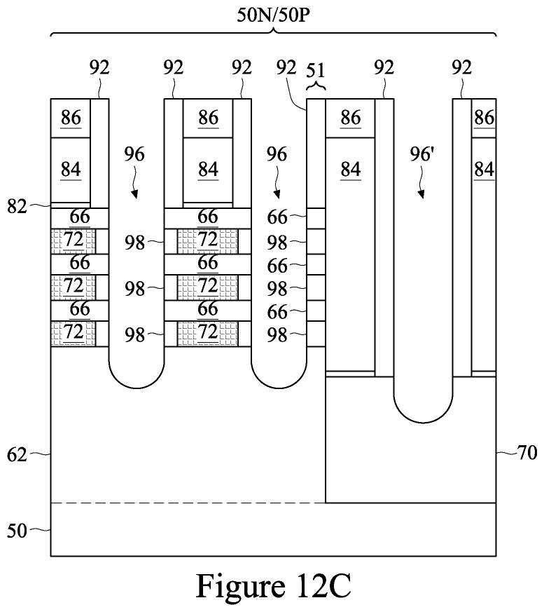

In FIGS. 12A-12C, inner spacers 98 are formed in the sidewall recesses 97, in accordance with some embodiments. In other words, inner spacers 98 are formed on the sidewalls of the dummy regions 72. As will be subsequently described in greater detail, source/drain regions are subsequently formed in the source/drain recesses 96, and the dummy regions 72 are subsequently replaced with corresponding gate structures. The inner spacers 98 act as isolation features between the subsequently formed source/drain regions and the subsequently formed gate structures. Further, the inner spacers 98 may be used to prevent damage to the subsequently formed source/drain regions by subsequent etch processes.

In some embodiments, the inner spacers 98 are formed by conformally depositing an insulating material in the source/drain recesses 96 and in the sidewall recesses 97 and subsequently etching the insulating material. The insulating material may be silicon nitride, silicon oxynitride, or the like. However, any suitable material, such as low-dielectric constant (low-k) materials having a k-value less than about 3.5, may be utilized. The insulating material may be formed by a deposition process, such as ALD, CVD, or the like. The etching of the insulating material may be anisotropic. For example, the etch process may be a dry etch such as a RIE, a NBE, or the like. After performing the etching of the insulating material, the remaining portions of the insulating material within the sidewall recesses 97 form the inner spacers 98. An inner spacer 98 may have a thickness that is smaller than, about the same as, or greater than a thickness of an adjacent dummy region 72.

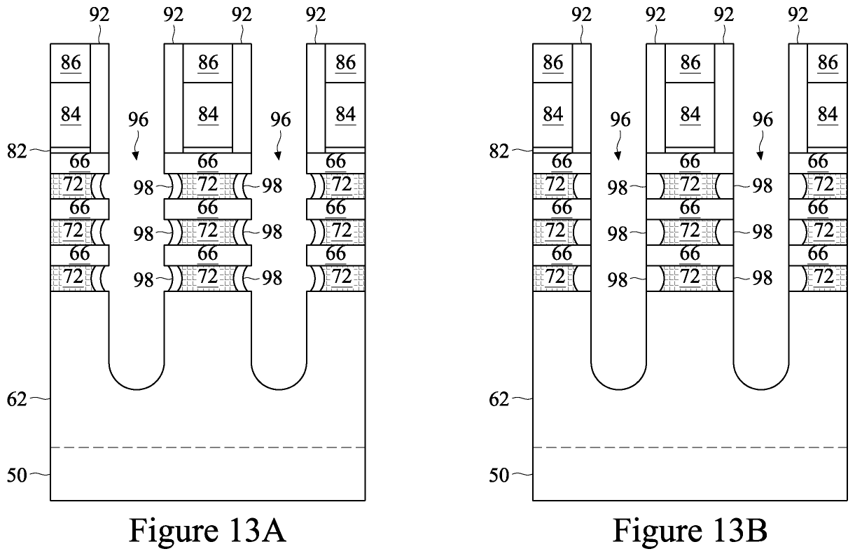

Although outer sidewalls of inner spacers 98 are illustrated as being flush (e.g. approximately coplanar) with sidewalls of the second nanostructures 66, the outer sidewalls of the inner spacers 98 may extend beyond or be recessed from sidewalls of the second nanostructures 66. In other words, the inner spacers 98 may partially fill, completely fill, or overfill the sidewall recesses 97. Moreover, although the sidewalls of the inner spacers 98 are illustrated as being flat in FIGS. 12A-12C, the sidewalls of the inner spacers 98 may be concave or convex. As an example, FIG. 13A illustrates an embodiment in which sidewalls of the dummy regions 72 are concave, outer sidewalls of the inner spacers 98 are concave, and inner spacers 98 are recessed from sidewalls of the nanostructures 66. As another example, FIG. 13B illustrates an embodiment in which sidewalls of the dummy regions 72 are concave, outer sidewalls of the inner spacers 98 are flat, and outer sidewalls of the inner spacers 98 are flush with sidewalls of the nanostructures 66. Other configurations or sidewall profiles are also possible.

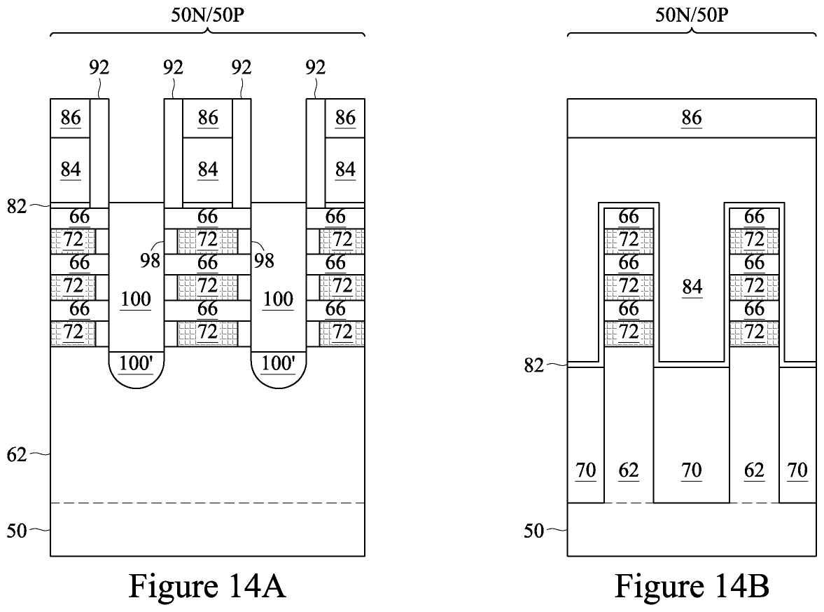

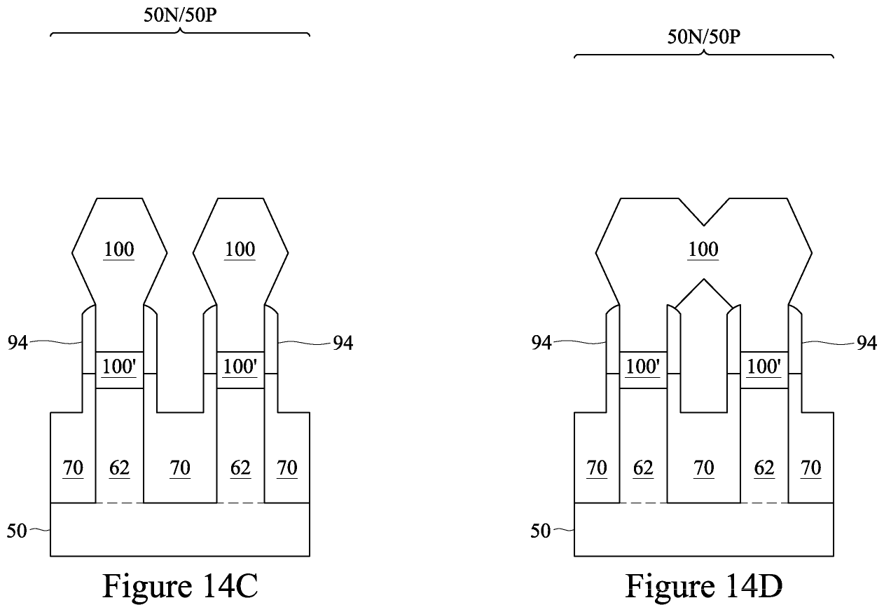

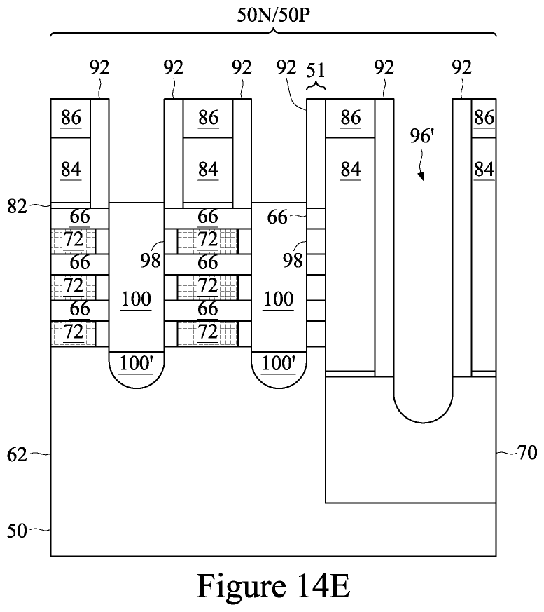

In FIGS. 14A-14E, epitaxial source/drain regions 100 are formed in the source/drain recesses 96 of the n-type region 50N and in the source/drain recesses 96 of the p-type region 50P, in accordance with some embodiments. The epitaxial source/drain regions 100 may also be referred to as “source/drain regions 100.” For example, the epitaxial source/drain regions 100 in the n-type region 50N may be referred to as “n-type source/drain regions,” and the epitaxial source/drain regions 100 in the p-type region 50P may be referred to as “p-type source/drain regions.” The n-type source/drain regions 100 may be formed before, after, or simultaneously with the formation of the p-type source/drain regions 100. The epitaxial source/drain regions 100 may be formed by an epitaxy process, such as such as vapor phase epitaxy (VPE), molecular beam epitaxy (MBE), or the like.

In some embodiments, a semiconductor layer 100′ may be formed in the source/drain recesses 96 before forming the epitaxial source/drain regions 100 in the source/drain recesses 96. The semiconductor layer 100′ may comprise, for example, undoped silicon or the like. Although the top surfaces of the semiconductor layers 100′ are illustrated as being flat (e.g., planar), the top surfaces of the semiconductor layers 100′ may be concave or convex. Top surfaces of the semiconductor layer 100′ may be higher than, approximately level with, or below top surfaces of the fins 62. In some embodiments, the semiconductor layer 100′ is not in physical contact with the inner spacers 98. In other embodiments, the semiconductor layer 100′ may be in physical contact with the sidewalls of some inner spacers 98. In some cases, the semiconductor layer 100′ may be considered part of the corresponding epitaxial source/drain region 100. In other embodiments, an insulating layer (not illustrated) may be deposited in the source/drain recesses 96 before forming the semiconductor layer 100′ and/or the epitaxial source/drain regions 100 in the source/drain recesses 96. The insulating layer may comprise, for example, a layer of silicon nitride, silicon oxide, or the like.

In some embodiments, the epitaxial source/drain regions 100 exert stress on channel regions of the nanostructures 66 within the n-type region 50N and/or within the p-type region 50P, thereby improving performance. The epitaxial source/drain regions 100 are formed in the source/drain recesses 96 such that each dummy gate 84 of the p-type region 50P is disposed between respective neighboring pairs of the epitaxial source/drain regions 100. In some embodiments, the gate spacers 92 are used to separate the epitaxial source/drain regions 100 from the dummy gates 84, and the inner spacers 98 are used to separate the epitaxial source/drain regions 100 from the nanostructures 66 by an appropriate lateral distance such that the epitaxial source/drain regions 100 do not short out with subsequently formed gates of the resulting nanostructure-FETs.

The epitaxial source/drain regions 100 in the n-type region 50N may be formed by masking the p-type region 50P. Then, n-type source/drain regions 100 are epitaxially grown in the source/drain recesses 96 in the n-type region 50N. The n-type source/drain regions 100 may include any acceptable material appropriate for n-type nanostructure-FETs. For example, if the nanostructures 66 are silicon, the n-type source/drain regions 100 may include materials exerting a tensile strain on the nanostructures 66, such as silicon, silicon carbide, phosphorous doped silicon carbide, silicon phosphide, or the like.

The epitaxial source/drain regions 100 in the p-type region 50P may be formed by masking the n-type region 50N. Then, p-type source/drain regions 100 are epitaxially grown in the source/drain recesses 96 in the p-type region 50P. The p-type source/drain regions 100 may include any acceptable material appropriate for p-type nanostructure-FETs. For example, if the nanostructures 66 are silicon, the p-type source/drain regions 100 may include materials exerting a compressive strain on the nanostructures 66, such as silicon germanium, boron doped silicon germanium, germanium, germanium tin, or the like.

The epitaxial source/drain regions 100, nanostructures 66, and/or the substrate 50 may be implanted with dopants to form source/drain regions, similar to the process previously discussed for forming lightly-doped source/drain regions, followed by an anneal. The source/drain regions may have an impurity concentration of between about 1×10¹⁹ atoms/cm³ and about 1×10²¹ atoms/cm³. The n-type and/or p-type impurities for source/drain regions may be any of the impurities previously discussed. In some embodiments, the epitaxial source/drain regions 100 may be in situ doped during growth.

As a result of the epitaxy processes used to form the epitaxial source/drain regions 100 in the n-type region 50N and the p-type region 50P, upper surfaces of the epitaxial source/drain regions 100 have facets which expand laterally outward beyond sidewalls of the nanostructures 66. In some embodiments, adjacent epitaxial source/drain regions 100 remain separated after the epitaxy process is completed, as illustrated by FIG. 14C. In other embodiments, these facets cause adjacent epitaxial source/drain regions 100 of a same nanostructure-FET to merge, as illustrated by FIG. 14D. In the embodiments illustrated in FIGS. 14C and 14D, the fin spacers 94 may be formed on top surfaces of the STI regions 70, thereby blocking epitaxial growth. In some other embodiments, the fin spacers 94 may cover portions of the sidewalls of the nanostructures 66, further blocking the epitaxial growth. In some other embodiments, the spacer etch used to form the fin spacers 94 may be adjusted to remove the spacer material to allow the epitaxially grown region to extend to the surface of the STI regions 70.

The n-type source/drain regions 100 and/or the p-type source/drain regions 100 may comprise one or more semiconductor material layers. Any number of semiconductor material layers may be used for the epitaxial source/drain regions 100. Each semiconductor material layer may be formed of different semiconductor materials and may be doped to different dopant concentrations. In embodiments in which the epitaxial source/drain regions 100 comprise three semiconductor material layers, the first semiconductor material layer may be deposited, the second semiconductor material layer may be deposited over the first semiconductor material layer, and the third semiconductor material layer may be deposited over the second semiconductor material layer. In some embodiments, the first semiconductor material layer may have a dopant concentration less than the second semiconductor material layer and greater than the third semiconductor material layer. Other semiconductor material layers, dopant concentrations, or configurations thereof are possible.

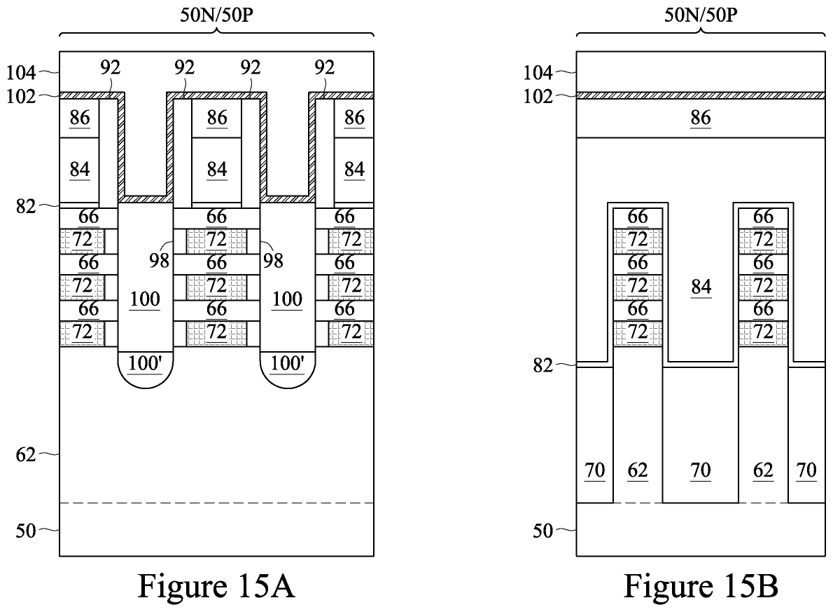

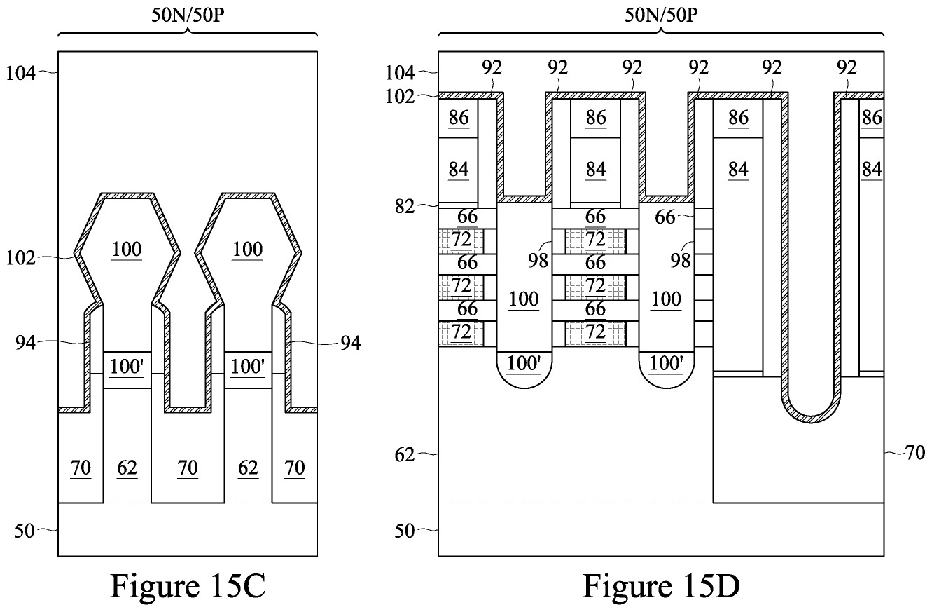

In FIGS. 15A-15D, a first ILD 104 is deposited over the epitaxial source/drain regions 100, the fin spacers 94, the gate spacers 92, the masks 86 (if present), and/or the dummy gates 84. The first ILD 104 may be formed of a dielectric material, which may be deposited by any suitable method, such as CVD, plasma-enhanced CVD (PECVD), or FCVD. Suitable dielectric materials may include silicon oxide, phospho-silicate glass (PSG), boro-silicate glass (BSG), boron-doped phospho-silicate glass (BPSG), undoped silicate glass (USG), or the like. Other insulation materials formed by any acceptable process may be used. In some cases, the first ILD 104 may extend below top surfaces of the STI regions 70 and/or below bottom surfaces of the epitaxial source/drain regions 100. In some embodiments, a capping layer (not illustrated) is formed over the first ILD 104. The capping layer may be formed, for example, by recessing the first ILD 104 using a dry or wet etching process and then depositing a dielectric material over the structure. The dielectric material may comprise one or more materials such as silicon nitride, silicon oxynitride, or the like. A planarization process, such as a CMP or grinding process, may then be performed to remove excess dielectric material from over the structure, with the remaining dielectric material over the first ILD 104 forming the capping layer.

In some embodiments, a contact etch stop layer (CESL) 102 is formed between the first ILD 104 and the epitaxial source/drain regions 100, the fin spacers 94, the gate spacers 92, the masks 86 (if present), and/or the dummy gates 84. The CESL 102 may be formed of a dielectric material having a high etching selectivity from the etching of the first ILD 104, such as silicon nitride, silicon oxide, silicon oxynitride, a combination thereof, or the like, which may be formed using any suitable deposition process, such as CVD, ALD, or the like.

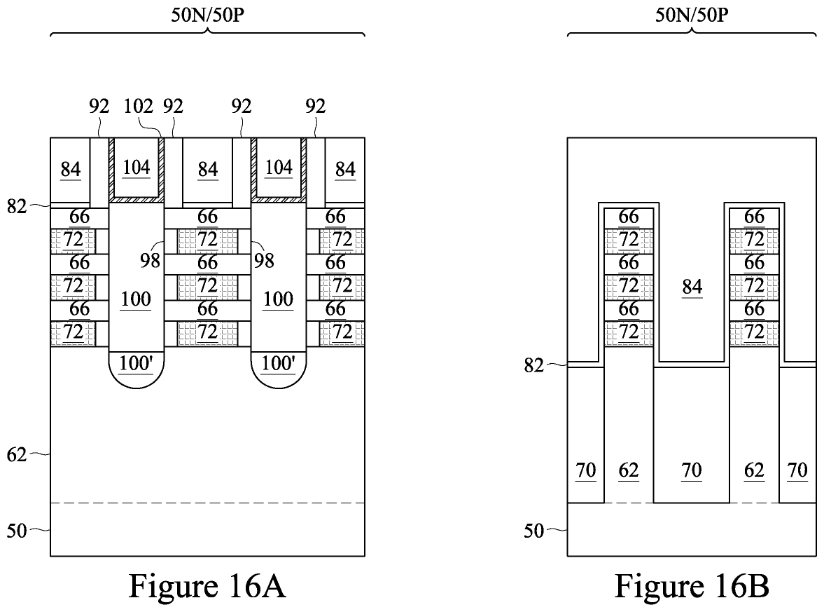

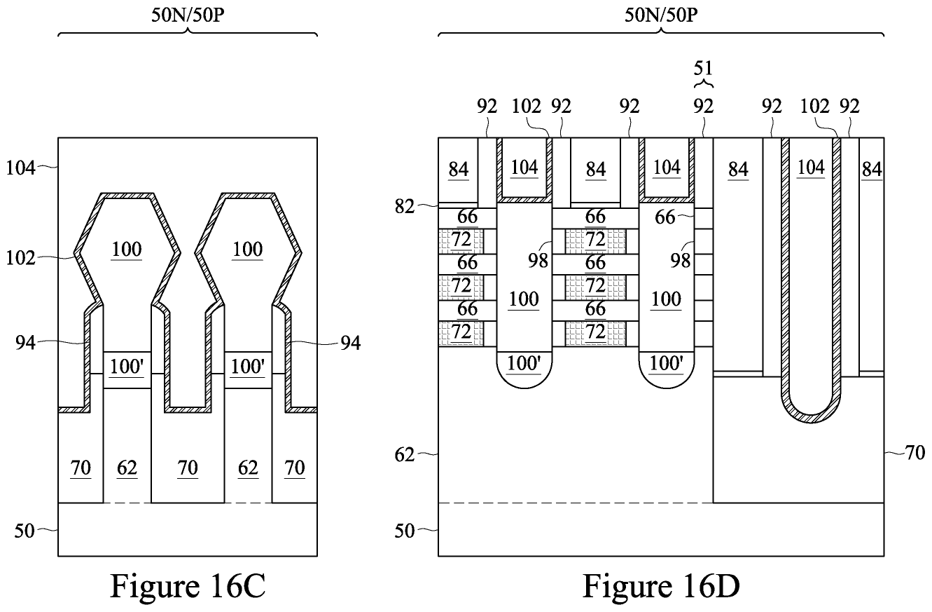

In FIGS. 16A-16D, a removal process is performed to level the top surfaces of the first ILD 104 with the top surfaces of the gate spacers 92 and the dummy gates 84, in accordance with some embodiments. In some embodiments, the planarization process removes the masks 86 and portions of the gate spacers 92 along sidewalls of the masks 86. The removal process may include a planarization process such as a chemical mechanical polish (CMP), a grinding process, an etch-back process, a combination thereof, or the like. After the planarization process, top surfaces of the first ILD 104, the gate spacers 92, and the dummy gates 84 may be substantially level or coplanar (within process variations). Accordingly, the top surfaces of the dummy gates 84 may be exposed through the first ILD 104. In other embodiments, the planarization process does not remove the masks 86. In such embodiments, after the planarization process, top surfaces of the first ILD 104, the gate spacers 92, and the masks 86 may be substantially level or coplanar (within process variations).

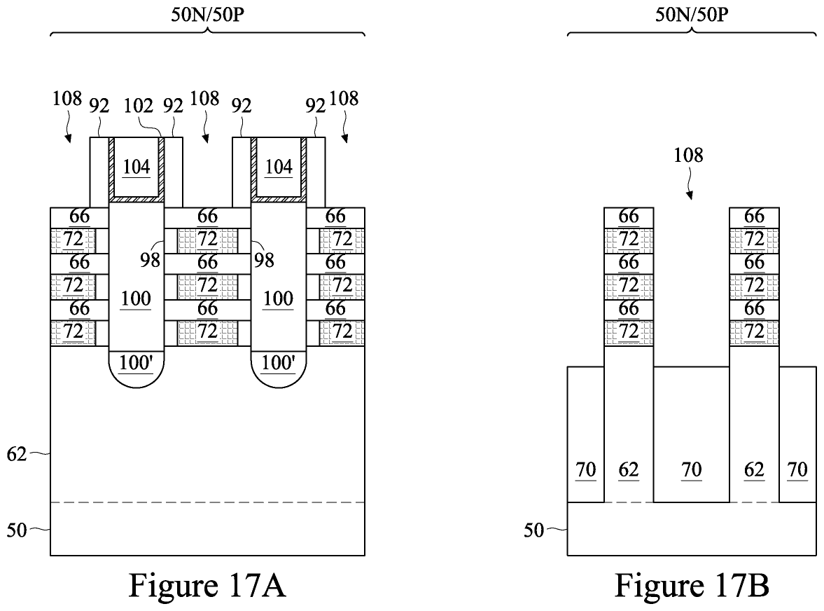

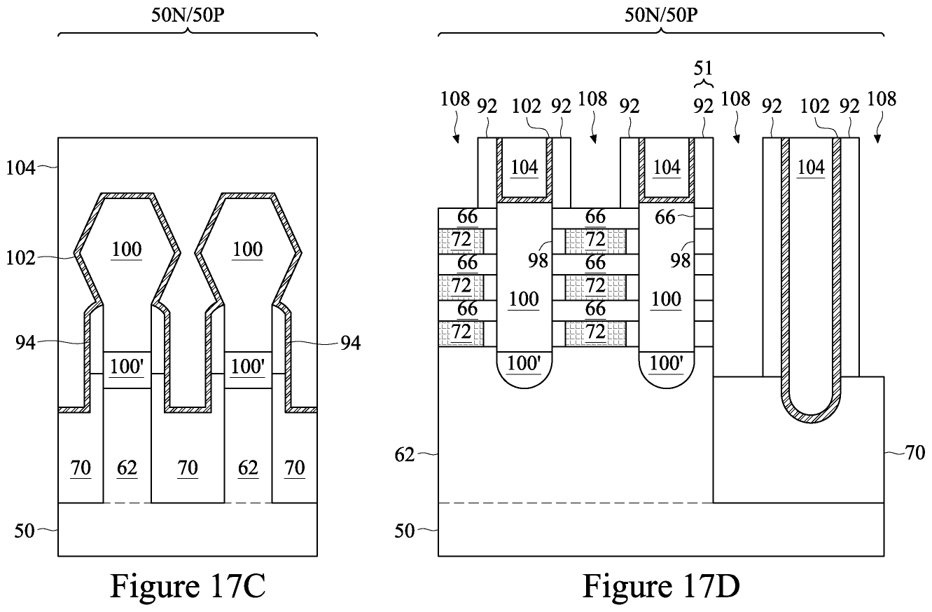

In FIGS. 17A-17D, the masks 86 (if present) and the dummy gates 84 are removed in one or more etching steps, such that recesses 108 are formed between the gate spacers 92. In some embodiments, the dummy gates 84 and the dummy dielectrics 82 are removed by an anisotropic dry etch process. For example, the etching process may include a dry etch process using reaction gas(es) that selectively etch the material of the dummy gates 84 at a faster rate than the materials of the first ILD 104 and the gate spacers 92. During the removal, the dummy dielectrics 82 may be used as etch stop layers when the dummy gates 84 are etched. The dummy dielectrics 82 may then be removed after the removal of the dummy gates 84.

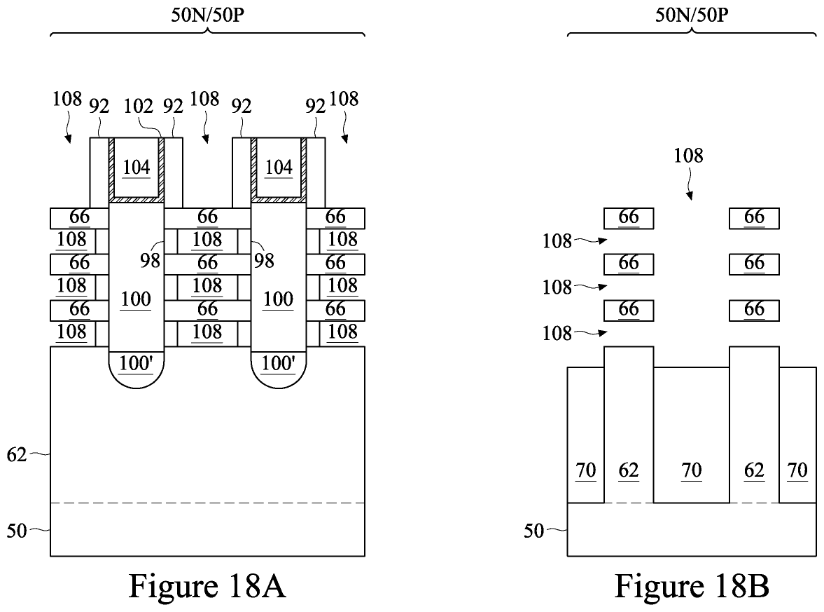

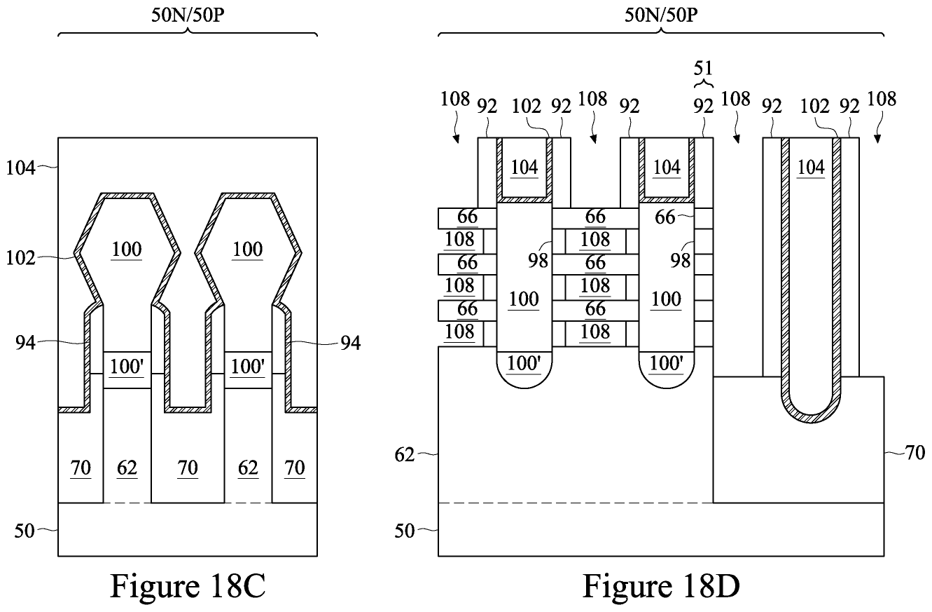

In FIGS. 18A-18D, the dummy regions 72 are removed, extending the recesses 108, in accordance with some embodiments. Removing the dummy regions 72 may include performing an isotropic etching process such as wet etching or the like. The etching process may use etchants which are selective to the materials of the dummy regions 72, while the nanostructures 66 remain relatively unetched as compared to the dummy regions 72. In some embodiments, the STI regions 70 may be at least partially etched while removing the dummy regions 72, but the total amount of loss in the STI regions 70 may be reduced by controlling etching parameters (e.g., timing) while removing the dummy regions 72. In other embodiments, the STI regions 70 may be protected from etching by a hard mask, such as the hard mask described previously for FIGS. 5A-5B.

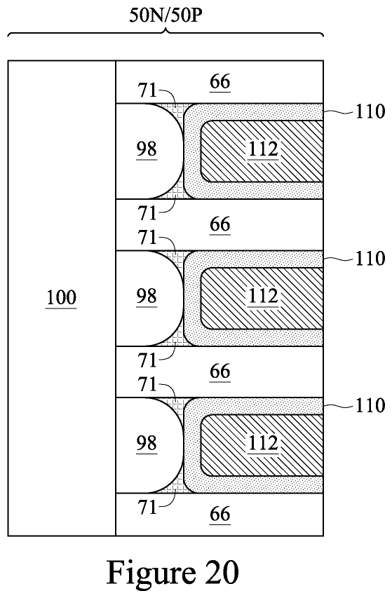

The dummy material 71 of the dummy regions 72 may be completely removed, or a residue of the dummy material 71 may remain on some sidewall portions of the inner spacers 98 in the recesses 108 (see e.g., FIG. 20). After removing the dummy regions 72, each recess 108 exposes portions of nanostructures 66, which act as channel regions in subsequently completed nanostructure-FETs. Portions of the nanostructures 66 which act as the channel regions are disposed between neighboring pairs of the epitaxial source/drain regions 100.

In some cases, replacing the first nanostructures 64 with dummy regions 72 can reduce the risk of undesired etching of the nanostructures 66 and/or the epitaxial source/drain regions 100 near the fin end regions 51. For example, etching processes used to remove the dummy regions 72 can have a higher selectivity than etching processes used to remove first nanostructures 64. In this manner, the use of dummy regions 72 and a more selective etch can reduce undesired etching of the nanostructures 66. In some cases, undesired etching of the nanostructures 66 in fin end regions 51 can result in adjacent source/drain regions 100 being etched or damaged. Accordingly, the use of dummy regions 72 and a more selective etch can reduce etching of the nanostructures 66 in the fin end regions 51 and thus can reduce or eliminate the risk of epitaxial source/drain region 100 damage near fin end regions 51. In some cases, the chance of epitaxial source/drain region 100 damage can be reduced or eliminated in some fin end regions 51 of a continuous fin structure formed by fins 62 having different offsets and/or widths (described in greater detail below).

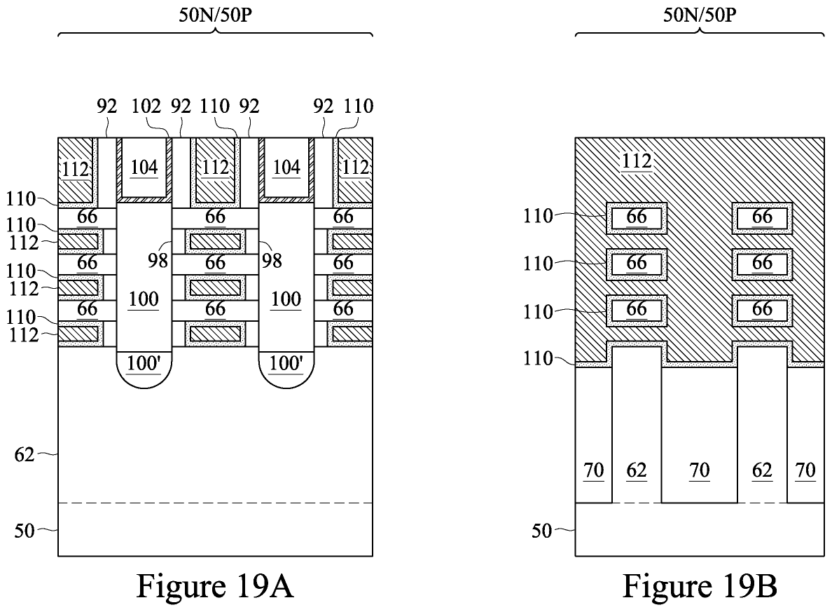

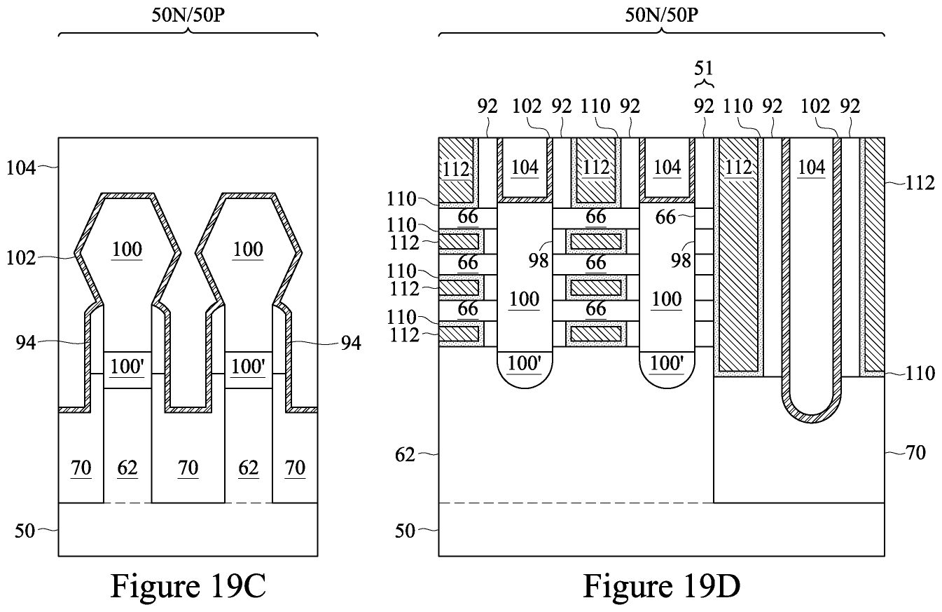

In FIGS. 19A-19D, gate dielectric layers 110 and gate electrodes 112 are formed for replacement gate structures, in accordance with some embodiments. The gate dielectric layers 110 are deposited conformally in the recesses 108. The gate dielectric layers 110 may be formed on top surfaces and sidewalls of the substrate 50 and on exposed top surfaces, sidewalls, and bottom surfaces of the nanostructures 66. The gate dielectric layers 110 may also be deposited on top surfaces of the first ILD 104, the CESL 102, the gate spacers 92, and the STI regions 70.

In accordance with some embodiments, the gate dielectric layers 110 comprise one or more dielectric layers, such as an oxide, a metal oxide, the like, or combinations thereof. For example, in some embodiments, the gate dielectric layers 110 may comprise a silicon oxide layer and a metal oxide layer over the silicon oxide layer. In some embodiments, the gate dielectric layers 110 include a high-k dielectric material, and in these embodiments, the gate dielectric layers 110 may have a k value greater than about 7.0, and may include a metal oxide or a silicate of hafnium, aluminum, zirconium, lanthanum, manganese, barium, titanium, lead, and combinations thereof. The structure of the gate dielectric layers 110 may be the same or different in the n-type region 50N and the p-type region 50P. The formation methods of the gate dielectric layers 110 may include molecular-beam deposition (MBD), ALD, PECVD, and the like.

The gate electrodes 112 are deposited over the gate dielectric layers 110, respectively, and fill the remaining portions of the recesses 108. The gate electrodes 112 may include a metal-containing material such as titanium nitride, titanium oxide, tantalum nitride, tantalum carbide, cobalt, ruthenium, aluminum, tungsten, combinations thereof, or multi-layers thereof. For example, although single layer gate electrodes 112 are illustrated in FIGS. 19A, 19B, and 10D, the gate electrodes 112 may comprise any number of liner layers, any number of work function tuning layers, and a conductive fill material. Any combination of the layers which make up the gate electrodes 112 may be deposited over surfaces of the nanostructures 66.

The formation of the gate dielectric layers 110 in the n-type region 50N and the p-type region 50P may occur simultaneously such that the gate dielectric layers 110 in each region are formed from the same materials, and the formation of the gate electrodes 112 may occur simultaneously such that the gate electrodes 112 in each region are formed from the same materials. In some embodiments, the gate dielectric layers 110 in each region may be formed by distinct processes, such that the gate dielectric layers 110 may be different materials and/or have a different number of layers, and/or the gate electrodes 112 in each region may be formed by distinct processes, such that the gate electrodes 112 may be different materials and/or have a different number of layers. Various masking steps may be used to mask and expose appropriate regions when using distinct processes.

After the filling of the recesses 108, a planarization process, such as a CMP, may be performed to remove the excess portions of the gate dielectric layers 110 and the material of the gate electrodes 112, which excess portions are over the top surface of the first ILD 104. The remaining portions of material of the gate electrodes 112 and the gate dielectric layers 110 thus form replacement gate structures of the resulting nanostructure-FETs. The gate electrodes 112 and the gate dielectric layers 110 may be collectively referred to as gate structures or gate stacks.

FIG. 20 illustrates a detailed view of various elements of FIG. 19A, including the epitaxial source/drain regions 100, the gate dielectric layers 110, the gate electrodes 112, the nanostructures 66, and the inner spacers 98. The view of FIG. 20 may be a magnified view of a portion of a nanostructure-FET in the n-type region 50N or the p-type region 50P. In some embodiments, illustrated by FIG. 20, a residue of the dummy material 71 may remain on the inner spacers 98, such as between the inner spacers 98 and the gate dielectric layers 110. For example, the dummy regions 72 may not be fully removed, and the gate dielectric layers 110 may be formed on the remaining dummy material 71 of the dummy regions 72. Because the dummy material 71 is an insulating material (e.g., silicon oxide or the like), the remaining residue may not significantly impact the electrical performance of the resulting device.

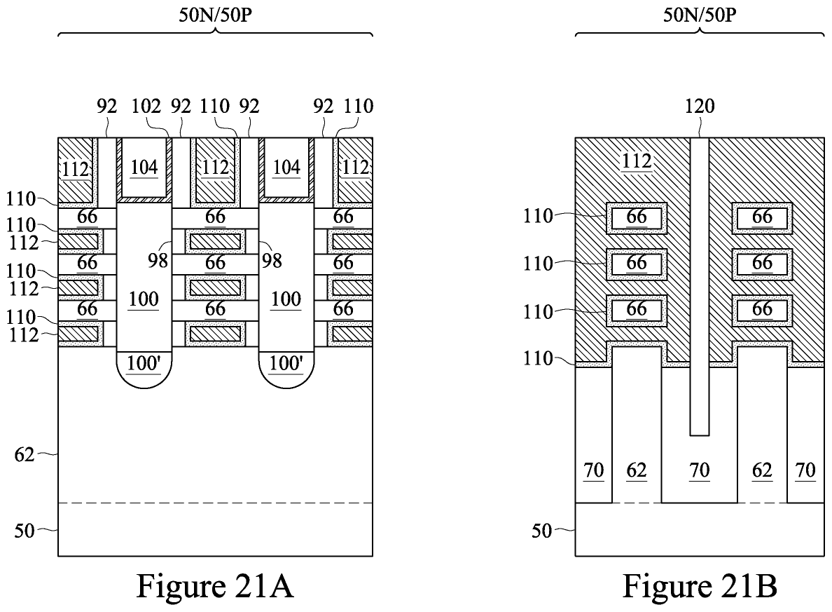

In FIGS. 21A-21B, gate isolation regions 120 are formed in the gate structures, in accordance with some embodiments. The gate isolation regions 120 separate (e.g., “cut”) gate structures into individual gate structures that may be physically and/or electrically isolated from each other. In some embodiments, the gate isolation regions 120 are formed by first forming trenches (not separately illustrated) extending through gate structures (e.g., through the gate electrodes 112 and the gate dielectric layers 110). The trenches may be formed using suitable photolithography and etching techniques. The etching may use a wet etching process and/or a dry etching process, which may be anisotropic. The trenches are then filled with insulating material. The insulating material may comprise one or more dielectric materials such as silicon nitride, silicon oxide, the like, or a combination thereof. In some cases, a liner or the like is deposited in the trench before depositing the insulating material. A planarization process (e.g., a CMP process, grinding process, or the like) may then be performed to remove excess insulating material. The remaining portions of the insulating material form the gate isolation regions 120. After performing the planarization process, top surfaces of the gate structures, the gate isolation regions 120, the first ILD 104, and the gate spacers 92 may be level or coplanar.

The gate isolation regions 120 may extend in a longitudinal direction that is parallel to the fins 62, and may extend between neighboring fins 62. As shown in FIG. 21B, the gate isolation regions 120 extend fully through the gate structures and may extend into the STI regions 70. The gate isolation regions 120 may extend below top surfaces of the STI regions 70. Because the gate isolation regions 120 are formed after formation of the gate structures, sidewalls of the gate isolation regions 120 are not covered by the gate dielectric layers 110, but the gate dielectric layers 110 may physically contact lower portions of the gate isolation regions 120 where the gate isolation regions 120 penetrate the gate dielectric layers 110. Accordingly, the gate electrodes 112 cover upper sidewalls of the gate isolation regions 120. For embodiments in which the gate electrodes 112 comprises multiple layers (e.g., liner layer(s), work function tuning layer(s), a conductive fill material, or the like), each layer may physically contact the gate isolation regions 120 where the gate isolation regions 120 penetrate the layers of the gate electrodes 112. In some cases, the conductive fill material of the gate electrodes 112 may cover upper sidewalls of the gate isolation regions 120. The gate isolation region 120 illustrated in FIG. 21B is an example, and gate isolation regions 120 may have other heights, widths, or sidewall profiles than shown. The gate isolation regions 120 are optional, and in other embodiments the gate isolation regions 120 are not formed.

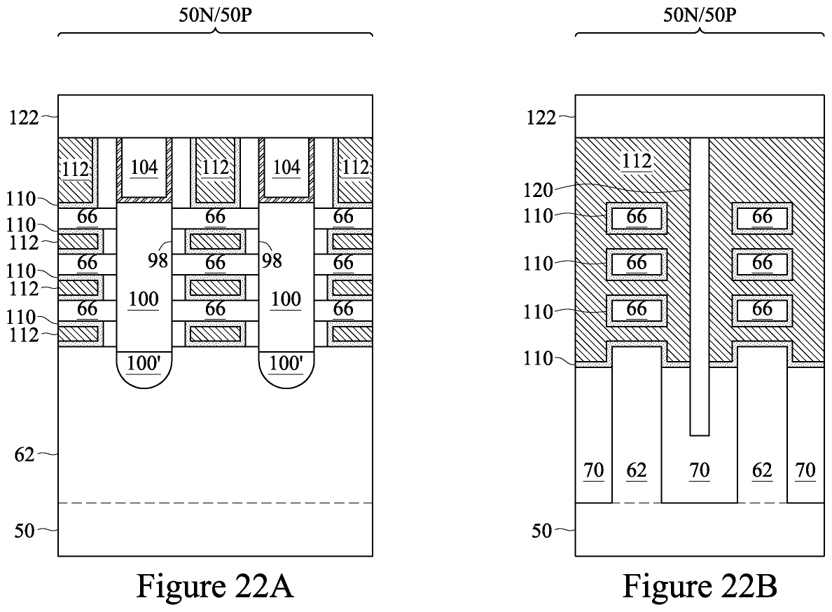

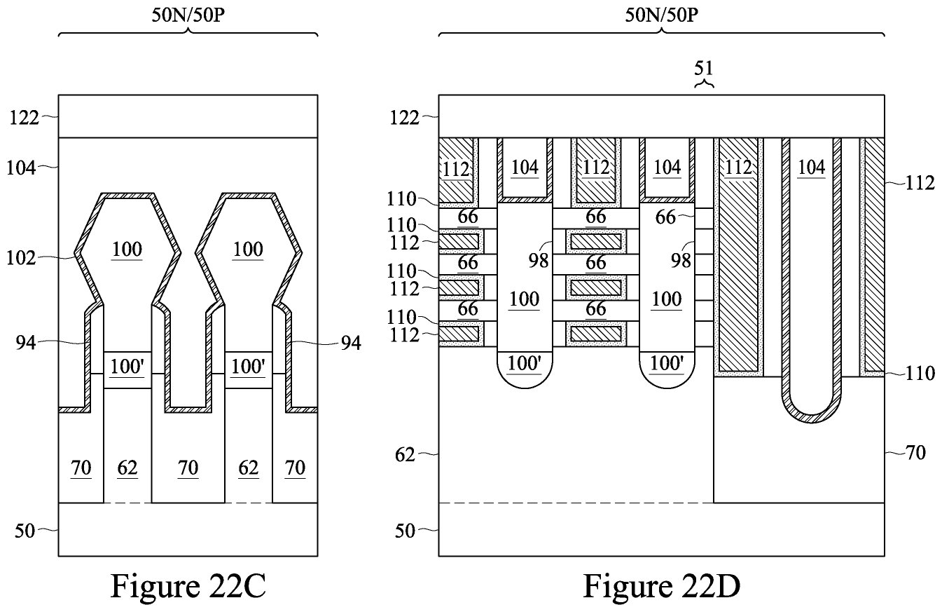

FIGS. 22A through 27D illustrate the formation of isolation regions 125 between fins 62, in accordance with some embodiments. The isolation regions 125 may physically separate adjacent fins 62. In some cases, the isolation regions 125 may separate (e.g., “cut”) continuous fin structures (described in greater detail below) into individual fins 62 that are physically and electrically isolated from each other. The isolation regions 125 may also separate gate structures into individual gate structures that may be physically and/or electrically isolated from each other. In some cases, the isolation regions 125 may be considered isolation structures, dielectric plugs, dummy fins, or the like. In some cases, the isolation regions 125 may be considered a Continuous Metal On-Diffusion Edge (CMODE) isolation region (also referred to as a Cut Metal on-Diffusion Edge (CMODE) isolation region) or a Continuous Poly On-Diffusion Edge (CPODE) isolation region.

In FIGS. 22A-22D, a hard mask layer 122 is formed over the gate structures, the first ILD 104, the gate spacers 92, the gate isolation regions 120. In some embodiments, the hard mask layer 122 may be a single layer of a suitable dielectric material, such as silicon nitride, silicon oxynitride, or the like. In some embodiments, the hard mask layer 122 is a multi-layered structure comprising layers of different materials. For example, the hard mask layers 122 may include a silicon layer sandwiched between two silicon nitride layers. The material(s) of the hard mask layer 122 may be formed using a suitable technique such as CVD or the like. Other materials or formation techniques are possible.

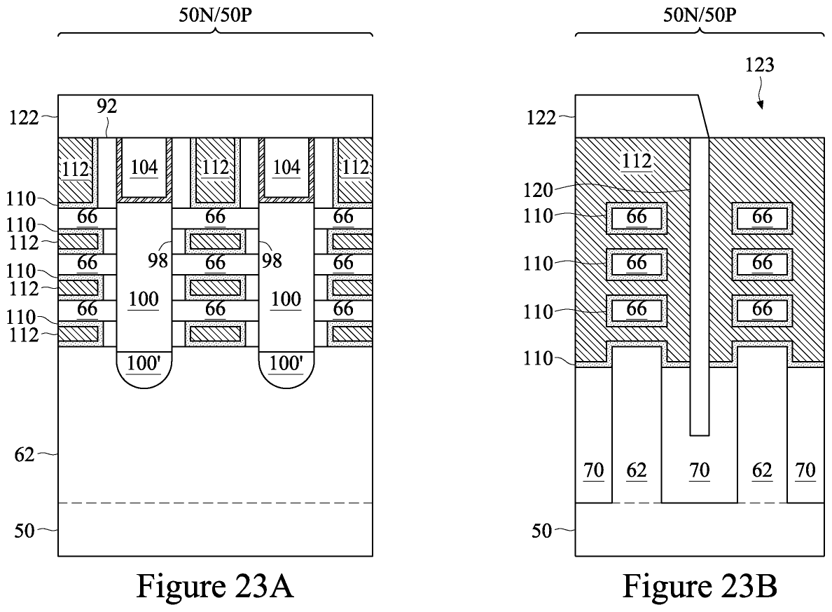

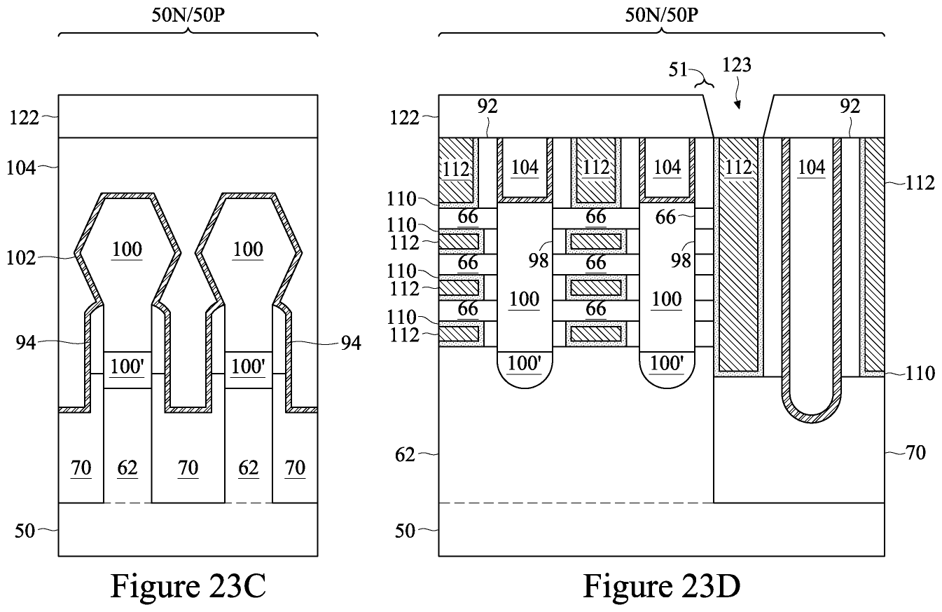

In FIGS. 23A-23D, openings 123 are patterned in the hard mask layer 122, in accordance with some embodiments. The openings 123 define regions of the structure that are subsequently replaced by the isolation regions 125. As shown in FIGS. 23A-23D, the openings 123 expose portions of gate structures 112. As shown in FIG. 23B, an opening 123 may expose a gate structure on one side of a gate isolation region 120 while leaving the hard mask layer 122 covering the gate structure on the opposite side of the gate isolation region 120. As shown in FIG. 23D, an opening 123 may expose a gate structure adjacent to a fin end region 51. The openings 123 may be formed using suitable photolithography and etching techniques. For example, an etching mask such as a photoresist, multi-layer mask structure, or the like may be formed over the hard mask layer 122 and patterned, with the pattern corresponding to the openings 123. The pattern may then be transferred to the hard mask layer 122 using an etching process to form the openings 123. The etching process may include one or more wet etching processes or dry etching processes, which may be anisotropic. The etching mask may then be removed using a suitable technique, such as etching, ashing, grinding or the like.

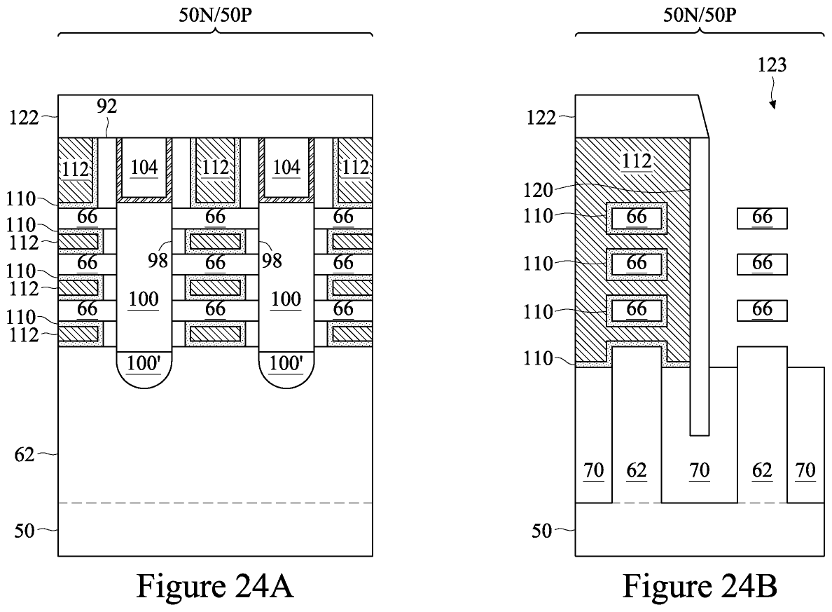

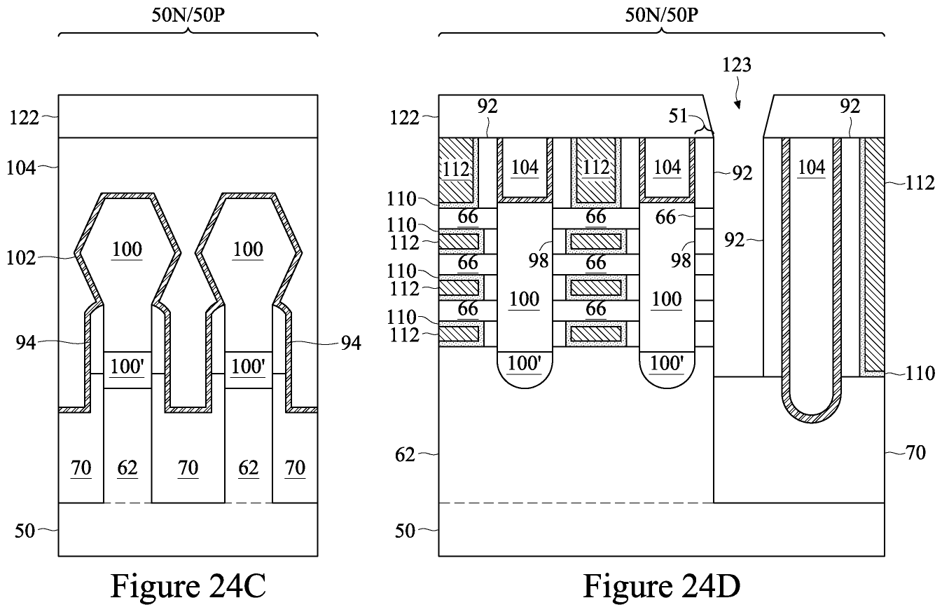

In FIGS. 24A-24D, the portions of the gate structures exposed by the openings 123 are removed, in accordance with some embodiments. In some embodiments, the portions of the gate structures are removed using one or more selective etching processes that etch the gate electrodes 112 and the gate dielectric layers 110 without significant etching of the nanostructures 66, fins 62, gate spacers 92, inner spacers 98, STI regions 70, and/or gate isolation regions 120. The etching processes may include wet etching processes or dry etching processes, which may be isotropic or anisotropic. For example, in some embodiments, a wet etching process is used to remove the gate structures. After the etching process, the gate electrodes 112 and the gate dielectric layers 110 in the exposed portions of the gate structures are removed (e.g., completely removed), and the openings 123 are extended downward through the gate structures to expose upper surfaces of the STI regions 70. The nanostructures 66 previously surrounded by the exposed portion of the gate structure are exposed to the opening 123. In other words, after performing the etching process(es), top surfaces, bottom surfaces, and/or sidewall surfaces of nanostructures 66 may be exposed. Additionally, upper portions of the fins 62 may be exposed, and top surfaces of STI regions 70 may be exposed. Removing the gate structures within the openings 123 may expose sidewall surfaces of fin end regions 51. For example, sidewalls of gate isolation regions 120, gate spacers 92, inner spacers 98, and nanostructures 66 may be exposed. For embodiments in which the gate isolation regions 120 are not formed, the selective etching processes may be anisotropic, which can reduce damage or unwanted etching of the sidewalls of the gate electrodes 112 exposed by the opening 123.

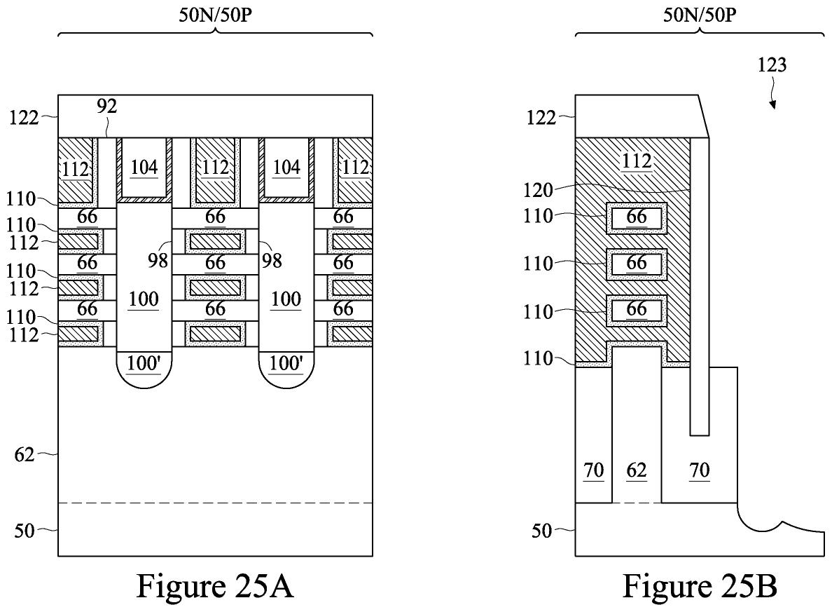

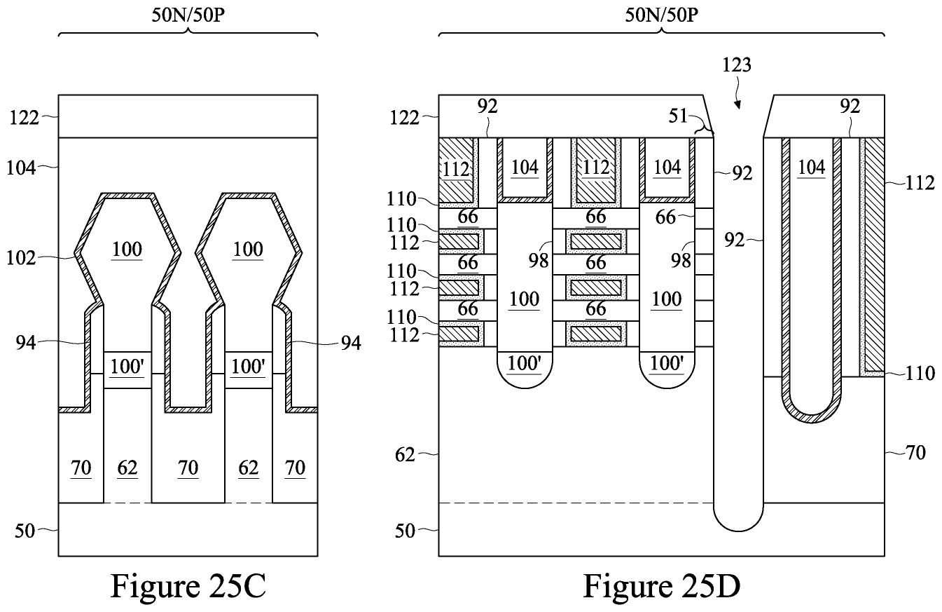

In FIGS. 25A-25D, an anisotropic etching process is performed to extend the openings 123 through the nanostructures 66 and fins 62, in accordance with some embodiments. The portions of the nanostructures 66 and fins 62 exposed by the openings 123 may be completely removed, in some embodiments. The openings 123 may be extended through portions of the STI regions 70 and into the substrate 50, in some embodiments. The anisotropic etching process may include, for example, a dry plasma etching process or the like. In some embodiments, the anisotropic etching process may comprise multiple cycles of a passivation layer deposition step and an anisotropic etching step. The anisotropic etching process may be performed until the openings 123 achieve a target depth, such as a depth below a top surface of the substrate 50.

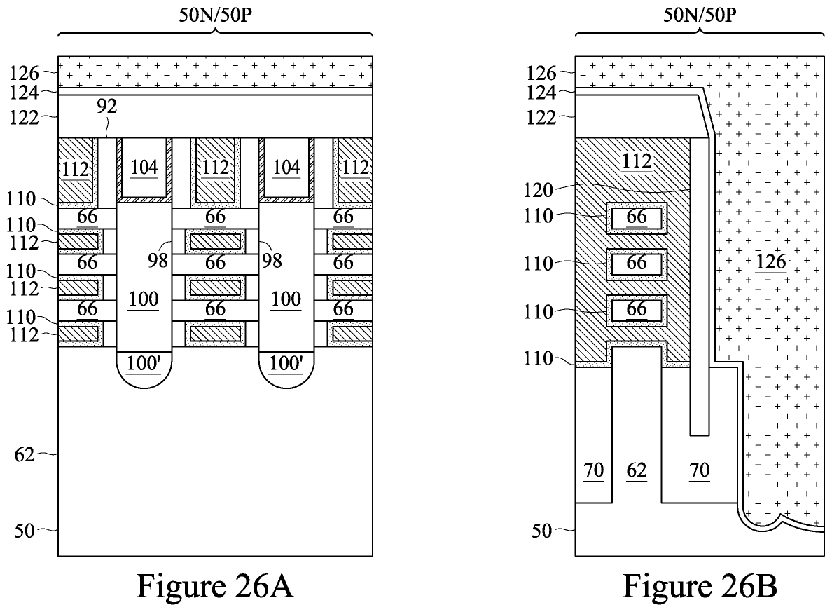

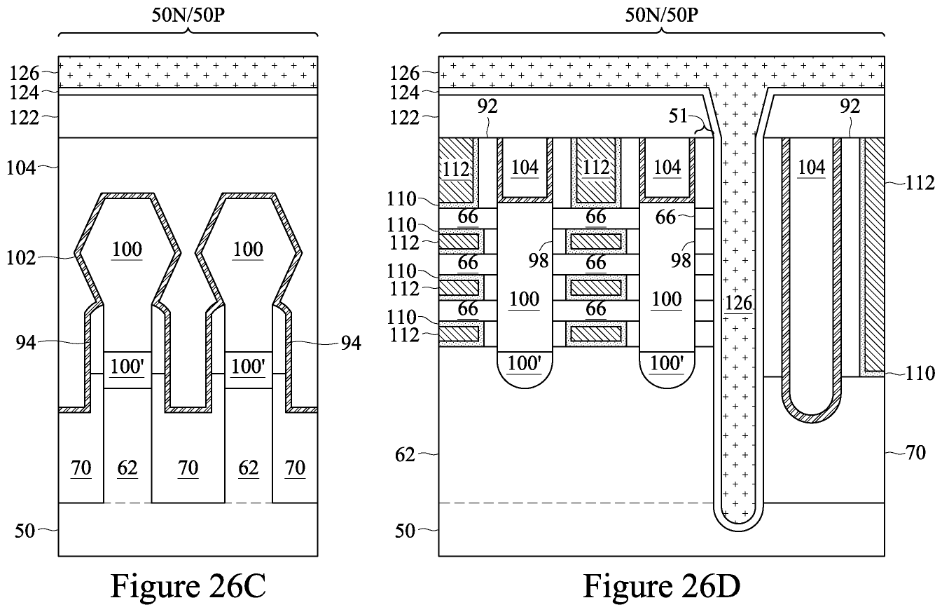

In FIGS. 26A-26D, one or more insulating materials of the isolation regions 125 are deposited over the hard mask layer 122 and in the openings 123. In some embodiments, a liner layer 124 is conformally deposited on the hard mask layer 122 and within the openings 123. The liner layer 124 may comprise a single layer of insulating material or may comprise multi-layers of insulating material(s). Then, a fill material 126 is deposited on the liner layer 124, filling the openings 123. The insulating materials may include, for example, dielectric materials such as silicon oxide, silicon nitride, silicon oxynitride, silicon oxycarbonitride, low-k materials, the like, combinations thereof, or multi-layers thereof. Any suitable formation techniques, such as CVD, PECVD, ALD, or the like, may be utilized. As an example, in some embodiments, the liner layer 124 comprises an oxide material and the fill material 126 comprises a nitride material. Other materials, layers, or formation techniques are possible.

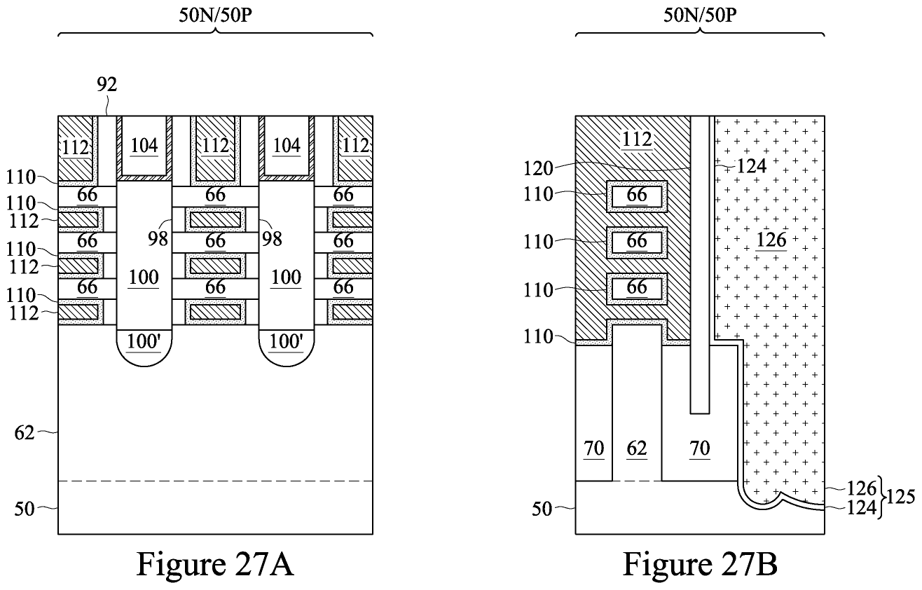

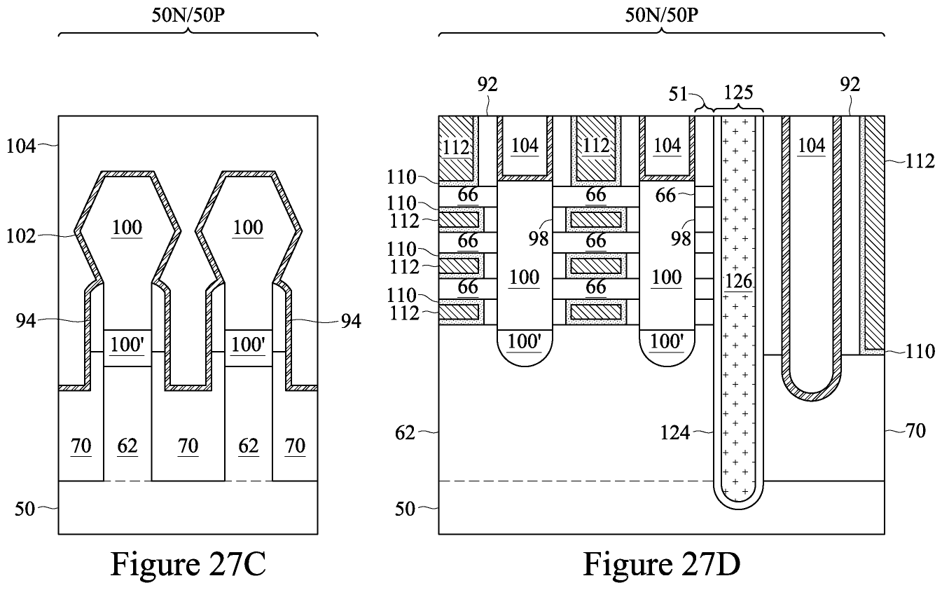

In FIGS. 27A-27D, a planarization process is performed to remove excess insulating material and the hard mask layer 122, in accordance with some embodiments. The remaining portions of the insulating material (e.g., the liner layer 124 and the fill material 126) form the isolation regions 125. The planarization process may include, for example, a CMP process, a grinding process, or the like. After performing the planarization process, top surfaces of isolation regions 125, gate structures, gate spacers 92, and the first ILD 104 may be level or coplanar. The isolation regions 125 may extend along portions of fin end regions 51 and may separate adjacent fin end regions 51, in some embodiments. As shown in FIGS. 27B and 27D, the layers of the gate structures (e.g., gate dielectric layers 110 and gate electrodes 112) are separated from the isolation regions 125 by the gate isolation regions 120, and thus the layers of the gate structures do not physically contact the sidewalls of the isolation regions 125. Additionally, because the isolation regions 125 are formed after the gate structures, the gate dielectric layers 110 do not extend along the sidewalls of the isolation regions 125.

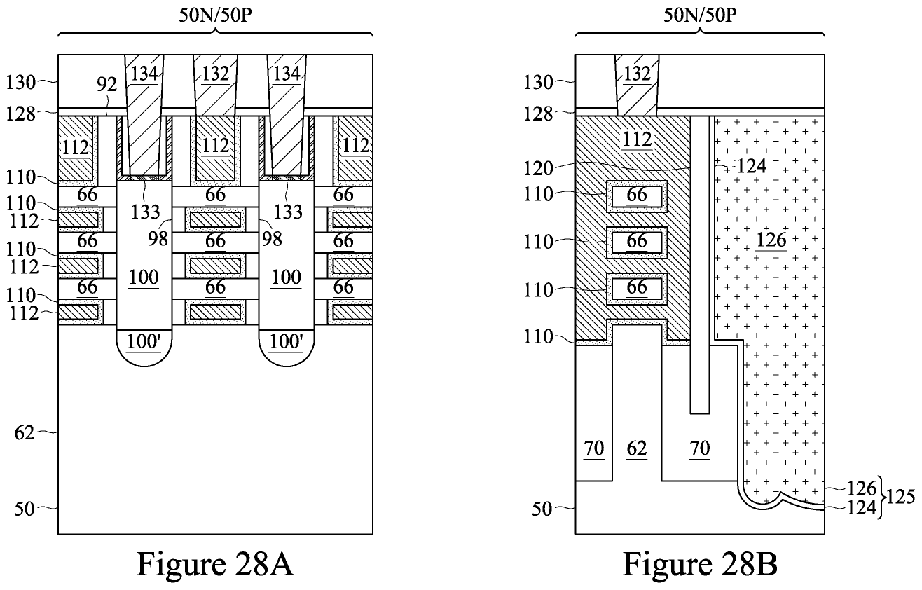

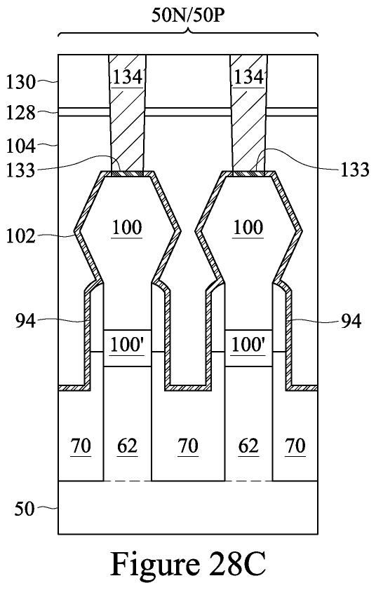

In FIGS. 28A-28C, a second ILD 130 is deposited over the gate spacers 92, the CESL 102, the first ILD 104, the gate structures, the gate isolation regions 120, and the isolation regions 125, in accordance with some embodiments. In some embodiments, the second ILD 130 is a flowable film formed by a flowable CVD method. In some embodiments, the second ILD 130 is formed of a dielectric material such as PSG, BSG, BPSG, USG, or the like, which may be formed by any suitable deposition process, such as CVD, PECVD, or the like.

In some embodiments, an etch stop layer (ESL) 128 is formed before deposition of the second ILD 130. The ESL 128 may be formed of a dielectric material having a high etching selectivity from the etching of the second ILD 130, such as silicon nitride, silicon oxide, silicon oxynitride, or the like, which may be formed by any suitable deposition process, such as CVD, ALD, or the like.

In other embodiments, the gate structures (including the gate dielectric layers 110 and the corresponding overlying gate electrodes 112) are recessed, so that recesses (not separately illustrated) are formed directly over the gate structures between opposing portions of gate spacers 92. A gate mask (not separately illustrated) comprising one or more layers of dielectric material, such as silicon nitride, silicon oxynitride, or the like, may be filled in the recesses, followed by a planarization process to remove excess portions of the dielectric material. Subsequently formed gate contacts (such as the gate contacts 132, discussed below) penetrate through the gate mask to contact the top surfaces of the recessed gate electrodes 112.

Further in FIGS. 28A-28C, gate contacts 132 and source/drain contacts 134 are formed to contact, respectively, the gate electrodes 112 and the epitaxial source/drain regions 100. The gate contacts 132 may be physically and electrically coupled to the gate electrodes 112. The source/drain contacts 134 may be physically and electrically coupled to the epitaxial source/drain regions 100.

As an example of forming the gate contacts 132 and the source/drain contacts 134, openings for the gate contacts 132 are formed through the second ILD 130 and the ESL 128, and openings for the source/drain contacts 134 are formed through the second ILD 130, the ESL 128, the first ILD 104, and the CESL 102. The openings may be formed using acceptable photolithography and etching techniques. A liner (not separately illustrated), such as a diffusion barrier layer, an adhesion layer, or the like, and a conductive material are formed in the openings. The liner may include titanium, titanium nitride, tantalum, tantalum nitride, or the like. The conductive material may be copper, a copper alloy, silver, gold, tungsten, cobalt, aluminum, nickel, or the like. A planarization process, such as a CMP, may be performed to remove excess material from a surface of the second ILD 130. The remaining liner and conductive material form the gate contacts 132 and the source/drain contacts 134 in the openings. The gate contacts 132 and the source/drain contacts 134 may be formed in distinct processes, or may be formed in the same process. Although shown as being formed in the same cross-sections, it should be appreciated that each of the gate contacts 132 and the source/drain contacts 134 may be formed in different cross-sections, which may avoid shorting of the contacts.

Optionally, metal-semiconductor alloy regions 133 are formed at the interfaces between the epitaxial source/drain regions 100 and the source/drain contacts 134. The metal-semiconductor alloy regions 133 can be silicide regions formed of a metal silicide (e.g., titanium silicide, cobalt silicide, nickel silicide, etc.), germanide regions formed of a metal germanide (e.g. titanium germanide, cobalt germanide, nickel germanide, etc.), silicon germanide regions formed of both a metal silicide and a metal germanide, or the like. The metal-semiconductor alloy regions 133 can be formed before the material(s) of the source/drain contacts 134 by depositing a metal in the openings for the source/drain contacts 134 and then performing a thermal annealing process. The metal can be any metal capable of reacting with the semiconductor materials (e.g., silicon, silicon carbide, silicon germanium, germanium, etc.) of the epitaxial source/drain regions 100 to form a low-resistance metal-semiconductor alloy, such as nickel, cobalt, titanium, tantalum, platinum, tungsten, other noble metals, other refractory metals, rare earth metals, or their alloys. The metal may be formed by a deposition process such as ALD, CVD, PVD, or the like. After the thermal annealing process, a cleaning process, such as a wet clean, may be performed to remove any residual metal from the openings for the source/drain contacts 134, such as from surfaces of the metal-semiconductor alloy regions 133. The material(s) of the source/drain contacts 134 can then be formed on the metal-semiconductor alloy regions 133.

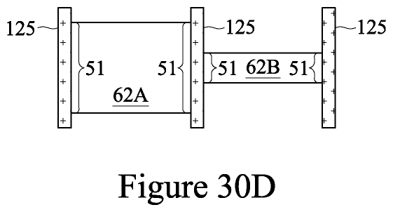

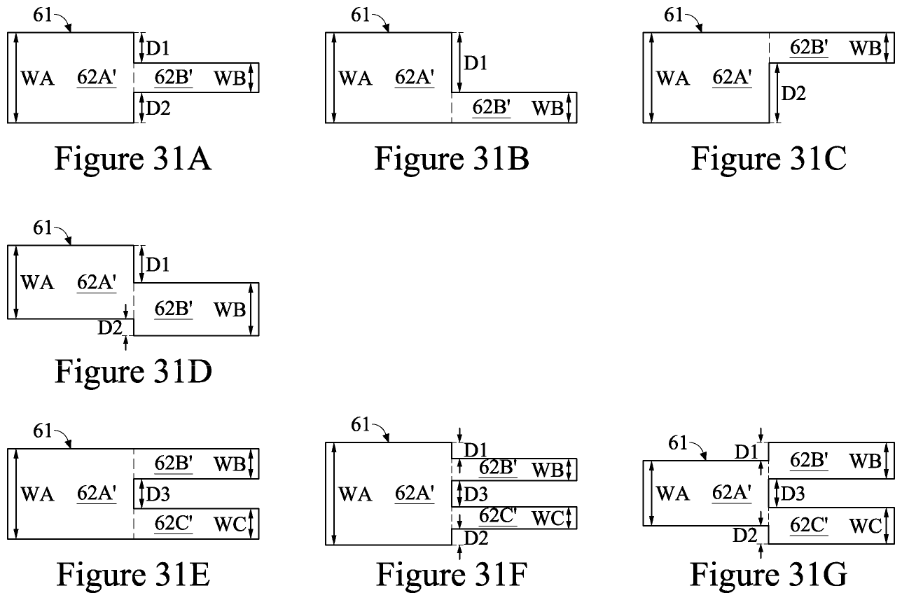

In some embodiments, the isolation regions 125 may be used to separate (e.g., “cut”) a continuous fin structure 61 into multiple, isolated fins 62. Accordingly, FIGS. 29A-29C illustrate plan views of example continuous fin structures 61 prior to separation, in accordance with some embodiments. FIGS. 30A-30D illustrate plan views of continuous fin structures 61 after being separated by isolation regions 125, in accordance with some embodiments. The illustrated continuous fin structures 61 and fins 62 are illustrative examples, and continuous fin structures 61 and fins 62 may have other sizes, shapes, dimensions, or arrangements in other embodiments. FIGS. 31A-31G, described in greater detail below, also illustrate non-limiting examples of continuous fin structures 61. While FIGS. 29A through 31G are described in terms of continuous fin structures 61 and fins 62, stacks of nanostructures 66 are typically present over the continuous fin structures 61 and fins 62. For example, an isolation region 125 may also separate one continuous stack of nanostructures 66 into multiple, isolated stacks of nanostructures 66. Accordingly, the following discussion regarding continuous fin structures 61 and fins 62 may also apply to the stacks of nanostructures 66 overlying the continuous fin structures 61 and fins 62.

FIGS. 29A-29C illustrate three example continuous fin structures 61 in a plan view, in accordance with some embodiments. The continuous fin structures 61 are continuous structures formed of fin portions 62′ (e.g., a fin portion 62A′, a fin portion 62B′, etc.) that are subsequently separated into corresponding individual fins 62 (e.g., fin 62A, fin 62B, etc.) by one or more isolation regions 125. The continuous fin structures 61 may be formed by appropriately patterning a multi-layer stack 52, which may be similar to the discussion of FIGS. 3A-3B above. Accordingly, the continuous fin structures 61 may be considered continuous structures formed from the multi-layer stack 52. The fin portions 62′ of a continuous fin structure 61 may include fin portions 62′ that are offset from each other and/or different fin portions 62′ having different widths. With reference to FIG. 1, the fin portions 62′ may extend in a longitudinal direction parallel to reference cross-section A-A′, and the isolation structures 125 may extend in a perpendicular direction such as the direction of reference cross-section B-B′ or C-C′. Accordingly, in some embodiments, two fin portions 62′ (e.g., a fin portion 62A′ and a fin portion 62B′) may be offset in a direction that is perpendicular (e.g., “perpendicularly offset”) to the longitudinal direction of the fin portions 62'. For example, the offset direction may be parallel to the direction of reference cross-section B-B′ or C-C′. In a plan view, a side of the continuous fin structure 61 may have a “step” due to the sidewall of one fin portion 62′ being perpendicularly offset from the sidewall of an adjacent fin portion 62′. Forming the fins 62 by separating a continuous fin structure 61 into individual fins 62 by forming isolation regions 125 may allow fins 62 of a device to be formed closer together, which can decrease device size and increase device density. FIGS. 29A-29C also indicate fin end regions 51 and offset end regions 51′ of continuous fin structures 61. The offset end regions 51′ are similar to the fin end regions 51, except that the offset end regions 51′ are end regions of a continuous fin structure 61 that are formed due to the fin portions 62′ being offset and/or having different widths. Accordingly, the offset end regions 51′ may include end regions at corners where the different fin portions 62′ of a continuous fin structure 61 meet. In some embodiments, isolation regions 125 are subsequently formed at or near the offset end regions 51′. In some cases, using dummy regions 72 as described previously can reduce the risk of nanostructure 66 damage and/or epitaxial source/drain region 100 damage at the offset end regions 51′, similar to the previous discussion for FIGS. 18A-18D.

FIG. 29A illustrates a continuous fin structure 61 comprising a relatively wide fin portion 62A′ that is continuous with a relatively narrow fin portion 62B′. An isolation region 125 is subsequently formed between the fin portion 62A′ and the fin portion 62B′ to form a fin 62A that is isolated and separated from a fin 62B (see FIG. 30A). As shown in FIG. 29A, the fin portion 62A′ and the fin portion 62B′ each have a fin end region 51. However, because the fin portion 62B′ is narrower than the fin portion 62A′, the fin portion 62A′ has offset end regions 51′ adjacent the fin portion 62B′.

The continuous fin structure 61 of FIG. 29B is similar to the continuous fin structure 61 of FIG. 29A, except that the continuous fin structure 61 of FIG. 29B comprises one wide fin portion 62A′ and two narrow fin portions 62B′ and 62C′. An isolation region 125 is subsequently formed between the fin portion 62A′ and the fin portions 62B′ and 62C′ to form isolated and separated fins 62A-C (see FIG. 30B). As shown in FIG. 29B, the fin portion 62A′, the fin portion 62B', and the fin portion 62C′ each have a fin end region 51. However, because the fin portions 62B′ and 62C′ are narrower than the fin portion 62A′, the fin portion 62A′ has offset end regions 51′ between the fin portions 62B′ and 62C′. In other embodiments, a continuous fin structure 61 may comprise a wide fin portion with more than two narrow fin portions.

The continuous fin structure 61 of FIG. 29C is similar to the continuous fin structure 61 of FIG. 29A, except that the continuous fin structure 61 of FIG. 29C comprises two offset fin portions 62A′ and 62B′. The fin portions 62A′ and 62B′ may have the same width or may have different widths. An isolation region 125 is subsequently formed between the fin portions 62A′ and 62B′ to form isolated and separated fins 62A-B (see FIG. 30C). As shown in FIG. 29C, the fin portions 62A′ and 62B′ each have a fin end region 51. However, because the fin portions 62A′ and 62B′ are offset from each other, each of the fin portions 62A′ and 62B′ also has an offset end region 51′.

FIGS. 30A-30C show the continuous fin structures 61 of FIGS. 29A-29C after isolation regions 125 have been formed to separate them into individual fins 62. For example, the isolation region 125 of FIG. 30A forms two separate fins 62A and 62B, the isolation region 125 of FIG. 30B forms three separate fins 62A, 62B, and 62C, and the isolation region 125 of FIG. 30C forms two separate fins 62A and 62B. The isolation regions 125 may be formed using materials or techniques similar to those described previously for FIGS. 22A-27D. As shown in FIGS. 30A-30C, the isolation regions 125 may be formed at offset end regions 51′ such that fin offset regions 51 of the isolated fins 62 are formed at one or both sides of the isolation regions 125. In some cases, the use of isolation regions 125 may allow for fins 62 to have a separation distance (e.g., an end-to-end distance) S1 that is in the range of about 20 nm to about 80 nm, though other separation distances are possible. In some cases, isolation regions 125 may be formed at or near fin end regions 51, as shown in the example of FIG. 30D, which shows the continuous fin structure 61 of FIG. 29A separated into fins 62A-B with three isolation regions 125.

FIGS. 31A-31G illustrate examples of various continuous fin structures 61 that may be formed, in accordance with some embodiments. The examples of FIGS. 31A-31G are non-limiting, and other shapes, configurations, or arrangements of continuous fin structures 61 are possible. For example, the fin portions 62′ (e.g., a fin portion 62A′, a fin portion 62B′, etc.) of a continuous fin structure 61 may have different widths or different offsets than shown, or the fin portions 62′ of a single continuous fin structure 61 may have a different number or arrangement than shown.

FIG. 31A illustrates a continuous fin structure 61 formed of a fin portion 62A′ and a fin portion 62B′. The continuous fin structure 61 of FIG. 31A may be subsequently separated into a fin 62A and a fin 62B by an isolation region 125, for example. The fin 62A may have a width WA in the range of about 5 nm to about 120 nm, and the fin 62B may have a width WB in the range of about 5 nm to about 120 nm that is less than the width WA. The offset D1 between the fin 62A and the fin 62B may be in the range of about 0 nm to about 115 nm, and the offset D2 may be in the range of about 0 nm to about 115 nm, such that the total sum of D1+D2 equals the difference WA−WB. FIG. 31B illustrates a continuous fin structure 61 formed of a fin portion 62A′ having a width WA in the range of about 5 nm to about 120 nm and a fin portion 62B′ having a width WB in the range of about 5 nm to about 120 nm that is less than the width WA. The offset D1 between the fin portion 62A′ and the fin portion 62B′ may be in the range of about 0 nm to about 115 nm, such that D1 equals the difference WA−WB. FIG. 31C illustrates a continuous fin structure 61 formed of a fin portion 62A′ having a width WA in the range of about 5 nm to about 120 nm and a fin portion 62B′ having a width WB in the range of about 5 nm to about 120 nm that is less than the width WA. The offset D2 between the fin portion 62A′ and the fin portion 62B′ may be in the range of about 0 nm to about 115 nm, such that D2 equals the difference WA−WB.

FIG. 31D illustrates a continuous fin structure 61 formed of a fin portion 62A′ having a width WA in the range of about 5 nm to about 120 nm and a fin portion 62B′ having a width WB in the range of about 5 nm to about 120 nm, in which the fin portion 62A′ is offset from the fin portion 62B′. The offset D1 between the fin 62A and the fin 62B may be in the range of about 0 nm to about 115 nm, and the offset D2 may be in the range of about 0 nm to about 115 nm.

FIG. 31E illustrates a continuous fin structure 61 formed of a fin portion 62A′ having a width WA in the range of about 20 nm to about 120 nm, a fin portion 62B′ having a width WB in the range of about 5 nm to about 120 nm, and a fin portion 62C′ having a width WC in the range of about 5 nm to about 120 nm, such that the widths WB and WC are each less than the width WA. The offset D3 between the fin 62B and the fin 62C may be in the range of about 5 nm to about 110 nm, such that the sum of WB+WC+D3 is equal to WA. FIG. 31F illustrates a continuous fin structure 61 formed of a fin portion 62A′ having a width WA in the range of about 20 nm to about 120 nm, a fin portion 62B′ having a width WB in the range of about 5 nm to about 120 nm, and a fin portion 62C′ having a width WC in the range of about 5 nm to about 120 nm, such that the widths WB and WC are each less than the width WA. The offset D1 between the fin 62B and the fin 62A may be in the range of about 0 nm to about 105 nm, the offset D2 between the fin 62C and the fin 62A may be in the range of about 0 nm to about 105 nm, and the offset D3 between the fin 62B and the fin 62C may be in the range of about 5 nm to about 110 nm, such that the sum of WB+WC+D1+D2+D3 is equal to WA. FIG. 31G illustrates a continuous fin structure 61 formed of a fin portion 62A′ having a width WA in the range of about 15 nm to about 120 nm, a fin portion 62B′ having a width WB in the range of about 5 nm to about 120 nm, and a fin portion 62C′ having a width WC in the range of about 5 nm to about 120 nm, in which the fin portion 62A′ is offset from the fin portion 62B′ and the fin portion 62C′. The offset D1 between the fin 62B and the fin 62A may be in the range of about 0 nm to about 105 nm, the offset D2 between the fin 62C and the fin 62A may be in the range of about 0 nm to about 105 nm, and the offset D3 between the fin 62B and the fin 62C may be in the range of about 5 nm to about 110 nm. Other widths or offsets are possible.

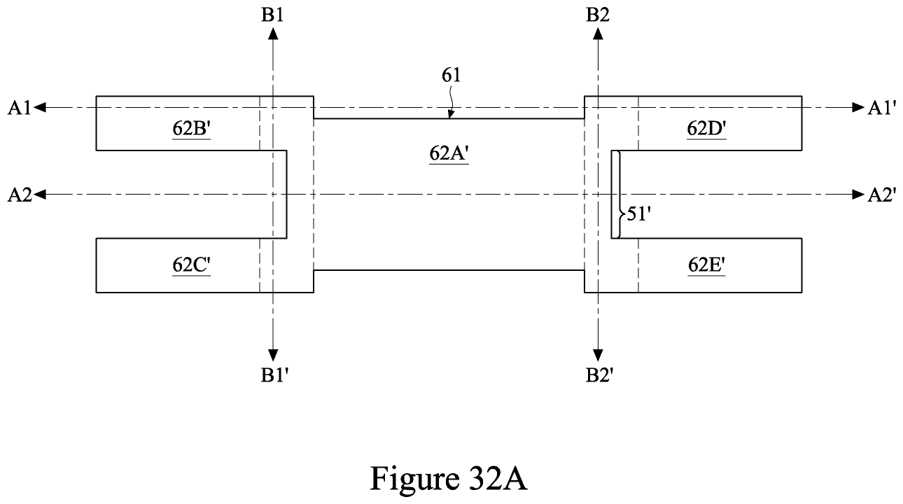

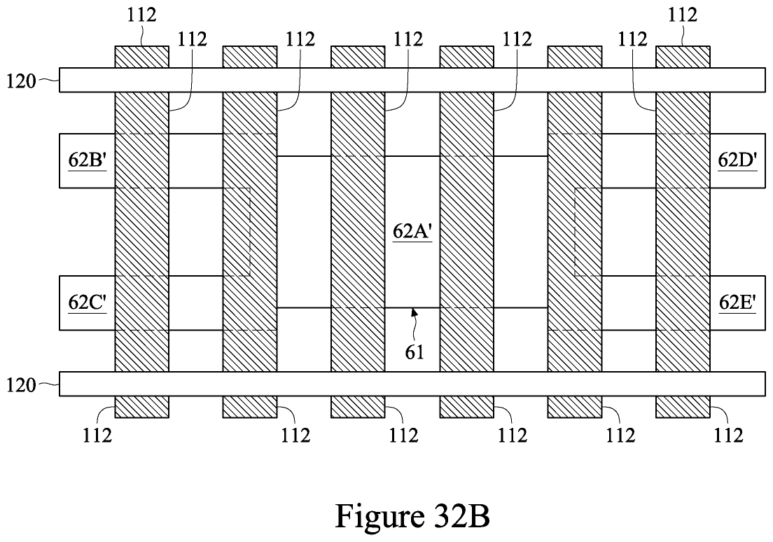

FIGS. 32A through 39 illustrate intermediate steps in the formation of nanostructure-FETs from a continuous fin structure 61, in accordance with some embodiments. As described in greater detail below, the continuous fin structure 61 is separated into individual fins 62A-E by isolation regions 125. Many of the materials, techniques, and features of FIGS. 32A-39 are similar to those described previously for FIGS. 2-27D, and some details are not repeated below. FIGS. 32A and 32B illustrate plan views of a continuous fin structure 61, in accordance with some embodiments. Similar to the previous discussion, the continuous fin structure 61 includes both fins 62 and overlying nanostructures 66. As shown in FIGS. 32A-32B, the continuous fin structure 61 comprises fin portions 62A′, 62B′, 62C′, 62D′, and 62E′, some of which have different widths and/or offsets. The subsequently formed isolation regions 125 separate the continuous fin structure 61 into a nanostructure-FET device comprising fin 62A, a nanostructure-FET device comprising fins 62B-C, and a nanostructure-FET device comprising fins 62D-E. Each nanostructure-FET device may comprise one or more nanostructure-FETs sharing the same gate structure.

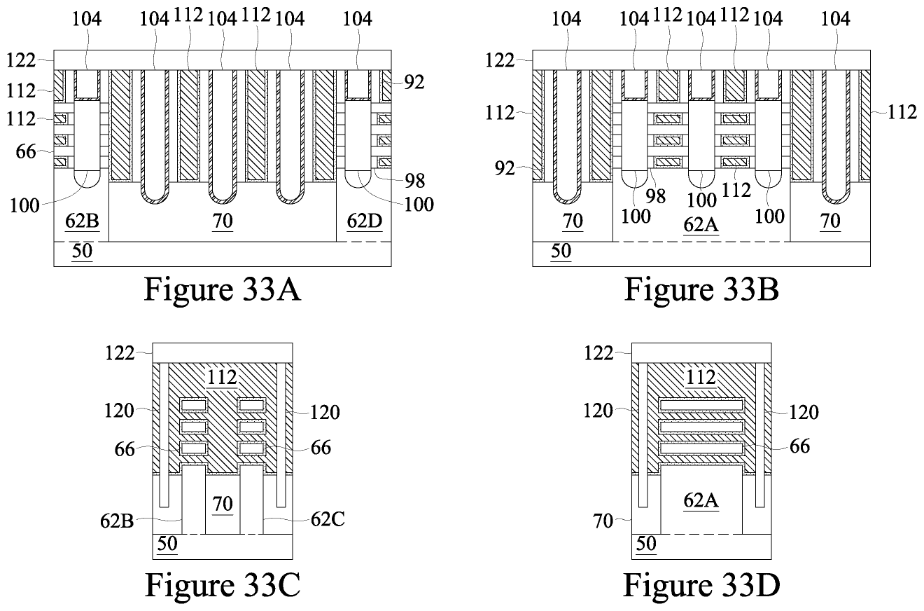

FIG. 32A shows a reference cross-section A1-A1′ through fin portions 62B′ and 62D′ and a reference cross-section A2-A2′ through fin portion 62A'. The reference cross-sections A1-A1′ and A2-A2′ are similar cross-sections as reference cross-section A-A′ in FIG. 1. FIG. 32A also shows a reference cross-section B1-B1′ and a reference cross-section B2-B2', which are similar cross-sections as reference cross-section B-B′ in FIG. 1. FIGS. 33A, 34A, 35A, 36A, and 37A illustrate cross-sectional views along a similar cross-section as reference cross-section A1-A1′ in FIG. 32A. FIGS. 33B, 34B, 35B, 36B, and 37B illustrate cross-sectional views along a similar cross-section as reference cross-section A2-A2′ in FIG. 32A. FIGS. 33C, 34C, 35C, 36C, and 37C illustrate cross-sectional views along a similar cross-section as reference cross-section B1-B1′ in FIG. 32A. FIGS. 33D, 34D, 35D, 36D, and 37D illustrate cross-sectional views along a similar cross-section as reference cross-section B2-B2′ in FIG. 32A.

FIG. 32A illustrates the continuous fin structure 61 corresponding, for example, to the process step shown in FIGS. 3A-3B. FIG. 32B illustrates a plan view of the continuous fin structure 61 after the formation of gate structures and gate isolation regions 120, in accordance with some embodiments. FIG. 32B illustrates the continuous fin structure 61 corresponding, for example, to the process step shown in FIGS. 21A-21B. As shown in FIG. 32B, the gate structures extend through the fin portions 62A′-62E′ and through portions of the continuous fin structure 61 between the fin portion 62A′ and the fin portions 62B′-62E′, which include offset end regions 51′. An example offset end region 51′ is indicated in FIG. 32A.

FIGS. 33A-33D illustrate the structure after formation of the hard mask layer 122, in accordance with some embodiments. The structure shown in FIGS. 33A-33D may be formed using materials and techniques similar to those described for FIGS. 2-22D. Accordingly, the hard mask layer 122 may be similar to the hard mask layer 122 of FIGS. 22A-D, and may be formed using similar techniques.

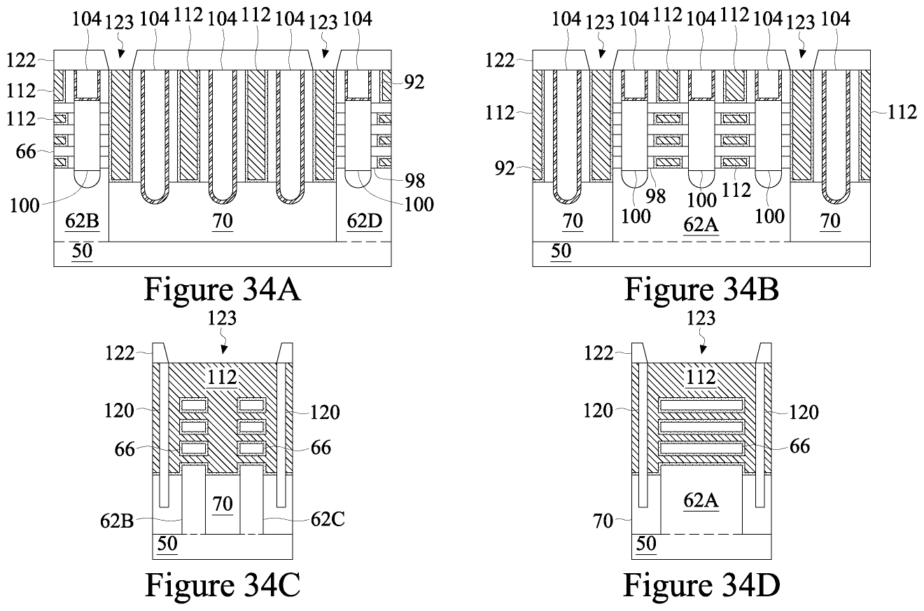

In FIGS. 34A-34D, openings 123 are patterned in the hard mask layer 122, in accordance with some embodiments. The openings 123 may be similar to the openings 123 described previously for FIGS. 23A-23D, and may be formed using similar techniques. For example, the openings 123 expose some gate structures, which may be adjacent to fin end regions 51 and/or gate isolation regions 120 in some cases.

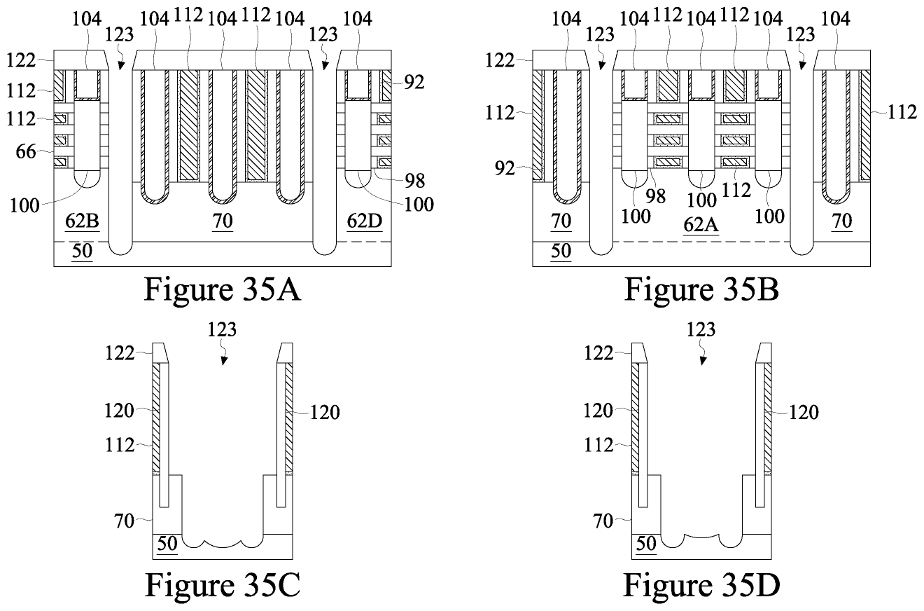

In FIGS. 35A-35D, one or more etching processes are performed to extend the openings 123 through the gate structures, the nanostructures 66, and fins 62, in accordance with some embodiments. The portions of the gate structures, nanostructures 66, and fins 62 exposed by the openings 123 may be completely removed, in some embodiments. The openings 123 may be extended through portions of the STI regions 70 and into the substrate 50. The openings 123 may be extended using etching techniques similar to those described previously for FIGS. 24A-25D. For example, the gate structures may be removed using a wet etching process and the nanostructures 66 and fins 62 may be removed using an anisotropic dry etching process, in some embodiments.

After performing the one or more etching processes, the bottom surfaces of the openings 123 may be flat, concave, convex, irregular, or another shape. For example, in some cases, the bottom surfaces of the openings 123 may have a “notched” or “scalloped” shape, as shown in FIGS. 35C and 35D. The shape or profile of the bottom surfaces of the openings 123 may be controlled, for example, by controlling the selectivity of the one or more etching processes. For example, if an etching process etches oxide at a greater rate than silicon, notches in bottom surfaces of the openings 123 may correspond to places where the openings 123 were extended through STI regions 70, ILD 104, or the like. As another example, if an etching process etches silicon at a greater rate than oxide, notches in bottom surfaces of the openings 123 may correspond to places where the openings 123 were extended through fins 62. In some cases, an etching process with an approximately equal selectivity between silicon and oxide may form relatively flat bottom surfaces of the openings 123. As an example, using more BCl₃ during an etching process may increase the etch rate of oxide relative to the etch rate of silicon, though other etchants or process gases may be used. These are examples, and the shapes of the bottom surfaces of the openings 123 may be affected by other conditions, etching parameters, etchants, structural configurations, or structural features.

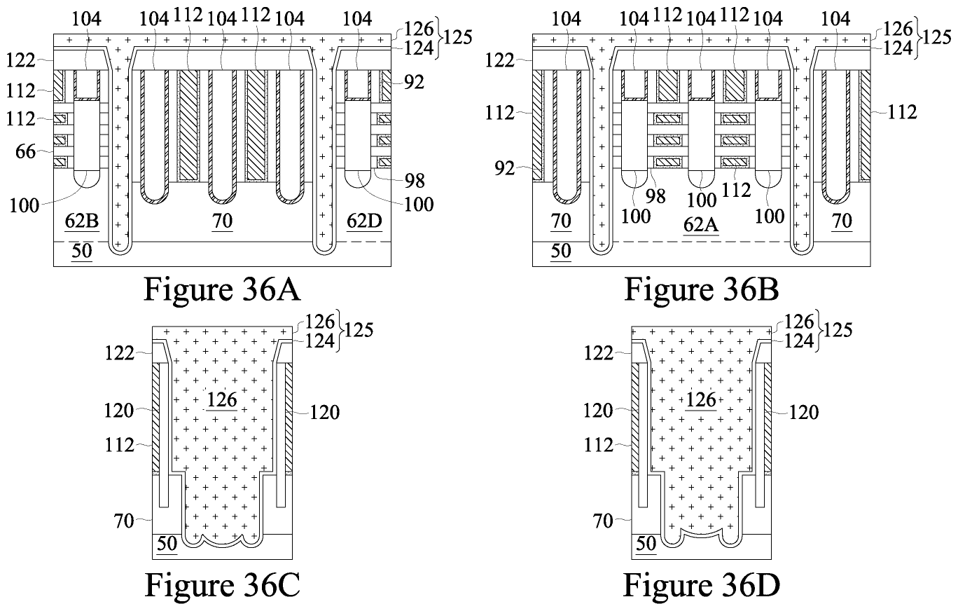

In FIGS. 36A-36D, the insulating material(s) of the isolation regions 125 are deposited over the hard mask layer 122 and in the openings 123, in accordance with some embodiments. The insulating materials may be similar to those described previously for FIGS. 26A-26D, and may be formed using similar techniques. For example, in some embodiments, a liner layer 124 is conformally deposited and then a fill material 126 is deposited on the liner layer 124, filling the openings 123. In some embodiments, the liner layer 124 comprises an oxide material and the fill material 126 comprises a nitride material. Other materials, layers, or formation techniques are possible.

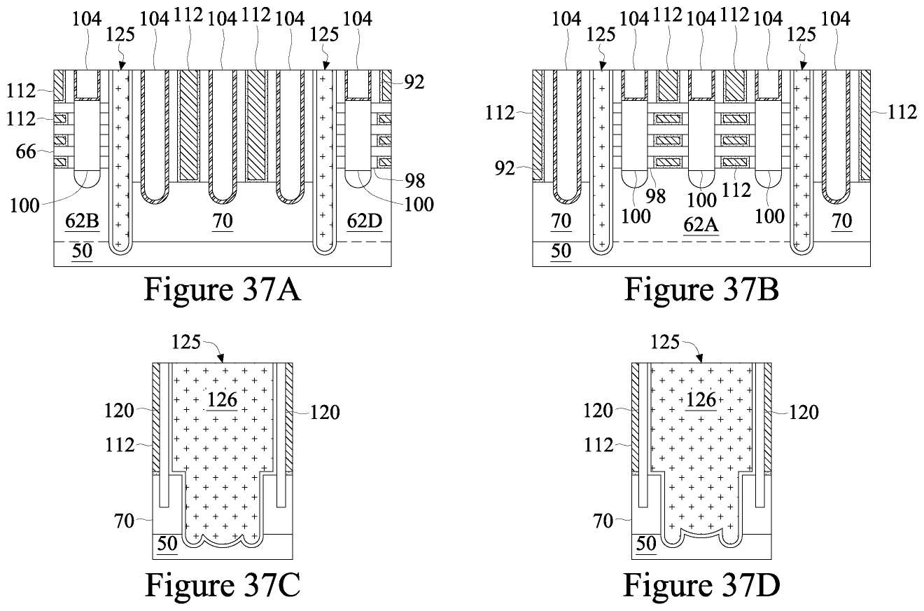

In FIGS. 37A-37D, a planarization process is performed to remove excess insulating material and the hard mask layer 122 to form the isolation regions 125, in accordance with some embodiments. After the planarization process the isolation regions 125 are formed by the remaining portions of the liner layer 124 and fill material. The planarization process may be similar to that described previously for FIGS. 27A-27D. For example, the planarization process may include, for example, a CMP process, a grinding process, or the like. The isolation regions 125 may extend along portions of fin end regions 51 and may separate adjacent fin end regions 51, in some embodiments. Subsequent processing may follow, such as process steps similar to those described previously for FIGS. 28A-28C.

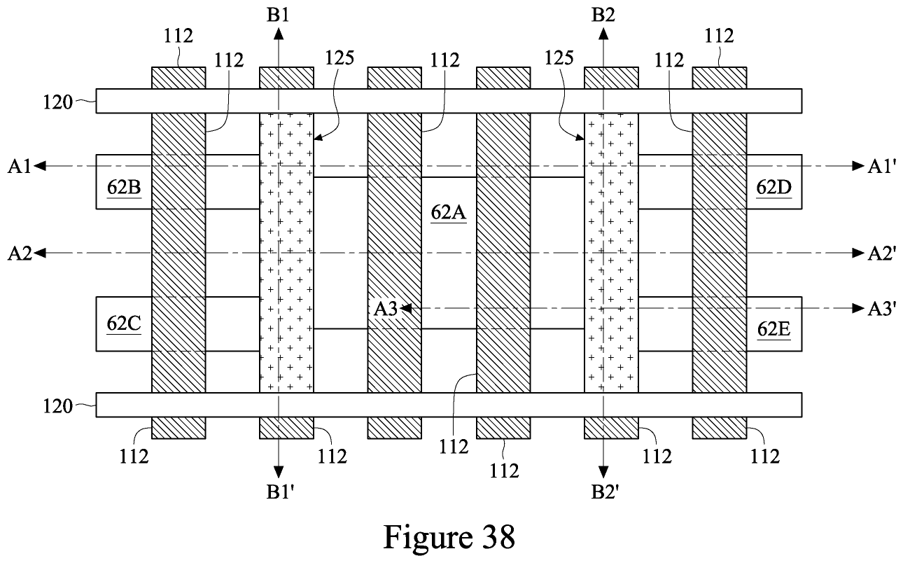

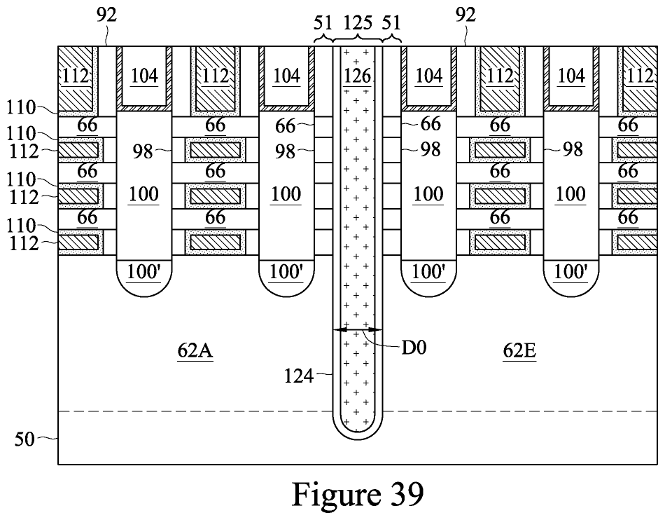

FIG. 38 illustrates a plan view of the fins 62A-E after formation of the isolation regions 125, in accordance with some embodiments. The plan view of FIG. 38 may correspond to the cross-sectional views of FIGS. 37A-37D. As shown in FIG. 38, the isolation regions 125 have separated the continuous fin structure 61 into separated fins 62A, 62B, 62C, 62D, and 62E. FIG. 38 shows a reference cross-section A3-A3′ through fins 62A and 62E, corresponding to the cross-sectional view of FIG. 39. The reference cross-section A3-A3′ is a similar cross-section as reference cross-section A-A′ in FIG. 1. FIG. 39 illustrates a cross-sectional view of fins 62A and 62E of FIG. 38, in accordance with some embodiments. As shown in FIG. 39, an isolation region 125 may separate fins 62, and thus may extend between fin end regions 51.

Embodiments may achieve advantages. The techniques described herein allow for the formation of isolation regions after formation of gate structures without increasing the risk of nanostructure or source/drain region damage due to etching. Forming isolation regions after the formation of gate structures can allow for smaller separation between fins. Additionally, forming isolation regions after the formation of gate structures rather than before the formation of gate structures can avoid process difficulties such as polysilicon deformation or the bending of features. Using dummy regions as described herein allows for improved etch selectivity when uncovering nanostructures prior to gate structure formation, which reduces the risk of etch damage to the nanostructures or source/drain regions. In particular, the use of dummy regions can reduce the risk of etch damage in offset end regions between offset fins and/or fins of different widths. Thus, the techniques described herein can improve yield, increase device density, and improve layout flexibility.

In an embodiment, a method includes forming a fin structure over a substrate; forming first nanostructures and second nanostructures over the fin structure, wherein the first nanostructures are continuous with respective second nanostructures; forming first dielectric dummy regions between ones of the first nanostructures, and second dielectric dummy regions between ones of the second nanostructures; forming first source/drain regions adjacent the first nanostructures and second source/drain regions adjacent the second nanostructures; performing an etching process to remove the first dielectric dummy regions and the second dielectric dummy regions; depositing gate structure layers on the first nanostructures and the second nanostructures; and forming an isolation region between the first nanostructures and the second nanostructures, wherein the isolation region physically separates the first nanostructures from the second nanostructures. In an embodiment, the first dielectric dummy regions include an oxide material. In an embodiment, the first nanostructures are wider than the second nanostructures. In an embodiment, forming the first dielectric dummy regions includes depositing a dielectric material on the first nanostructures and the second nanostructures; and
etching the dielectric material to expose sidewalls of the first nanostructures and the second nanostructures. In an embodiment, the isolation region extends below a top surface of the substrate. In an embodiment, forming the isolation region includes forming an opening in the gate structure layers and depositing insulating material in the opening. In an embodiment, sidewalls of the first nanostructures are offset from sidewalls of the second nanostructures. In an embodiment, the method includes forming a gate isolation region extending through the gate structure layers.

In an embodiment, a method includes forming a first nanostructure stack adjacent a second nanostructure stack, wherein the first nanostructure stack and the second nanostructure stack include first nanostructures and second nanostructures, wherein a first sidewall of the first nanostructure stack is adjacent a second sidewall of the second nanostructure stack, wherein the first sidewall is perpendicularly offset from the second sidewall; replacing the first nanostructures of the first nanostructure stack and the first nanostructures of the second nanostructure stack with dielectric regions; replacing the dielectric regions of the first nanostructure stack and the dielectric regions of the second nanostructure stack with a continuous gate structure; and replacing a portion of the continuous gate structure with an isolation region, wherein the isolation region extends between the first nanostructure stack and the second nanostructure stack. In an embodiment, before replacing the portion of the continuous gate structure with the isolation region, the first nanostructure stack is continuous with the second nanostructure stack. In an embodiment, the first nanostructures are a first semiconductor material and the second nanostructures are a second semiconductor material that is different from the first semiconductor material. In an embodiment, replacing the portion of the continuous gate structure with the isolation region includes: performing a first etch process that removes the portion of the continuous gate structure to form an opening; performing a second etch process that removes second nanostructures within the portion of the continuous gate structure to expand the opening; and filling the opening with an insulating material. In an embodiment, replacing the dielectric regions includes etching the dielectric regions with an etchant that selectively etches the dielectric regions at a greater rate than the second nanostructures. In an embodiment, portions of the dielectric regions remain on sidewalls of the continuous gate structure.

In an embodiment, a device includes a first fin and a second fin over a semiconductor substrate, wherein the first fin has a first width and the second fin has a second width different from the first width; first nanostructures over the first fin; second nanostructures over the second fin; a first gate structure over the first fin, wherein the first gate structure separates respectively adjacent first nanostructures; and a second gate structure over the second fin, wherein the second gate structure separates respectively adjacent second nanostructures; and an isolation structure extending from the first fin to the second fin, wherein the isolation structure protrudes into the semiconductor substrate. In an embodiment, a distance between the first fin and the second fin is in the range of 20 nm to 80 nm. In an embodiment, the device includes a shallow trench isolation (STI) region surrounding the first fin, wherein the isolation structure extends between the first fin and the STI region. In an embodiment, a difference between the first width and the second width is in the range of 5 nm to 115 nm. In an embodiment, the device includes a third fin over the semiconductor substrate, wherein the isolation structure extends from the first fin to the third fin. In an embodiment, a sidewall of the first fin is fully covered by the isolation structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a first fin and a second fin over a substrate, wherein a first sidewall of the first fin is contiguous with a second sidewall of the second fin, wherein a first width of the first sidewall is larger than a second width of the second sidewall;
forming a first stack of nanostructures over the first fin and a second stack of nanostructures over the second fin, wherein the first stack of nanostructures and the second stack of nanostructures comprise alternating layers of dielectric nanostructures and first semiconductor nanostructures;
performing a first etching process to remove the dielectric nanostructures of the first stack of nanostructures and of the second stack of nanostructures;
forming a gate structure on the first semiconductor nanostructures of the first stack of nanostructures and of the second stack of nanostructures;
performing a second etching process to form a recess that extends through the first fin, the second fin, and the gate structure; and
depositing an insulating material in the recess to form an isolation structure between the first fin and the second fin.

2. The method of claim 1, further comprising forming the layers of dielectric nanostructures, comprising:
forming second semiconductor nanostructures;
removing the second semiconductor nanostructures to form a plurality of openings; and
depositing a dielectric material in the plurality of openings.

3. The method of claim 1, wherein the recess extends into the substrate.

4. The method of claim 1, wherein the second etching process etches the first sidewall and the second sidewall.

5. The method of claim 1, wherein the insulating material contacts the first semiconductor nanostructures of the first stack of nanostructures and of the second stack of nanostructures.

6. The method of claim 1, further comprising forming a third fin over the substrate, wherein a third sidewall of the third fin is contiguous with the first sidewall of the first fin, wherein a first width of the first sidewall is larger than a third width of the third sidewall.

7. The method of claim 1, wherein the first stack of nanostructures has the first width and the second stack of nanostructures has the second width.

8. The method of claim 1, further comprising forming a dielectric region surrounding the first fin and the second fin, wherein the insulating material extends on a top surface of the dielectric region.

9. A method comprising:
forming a first fin over a substrate;
forming a first nanostructure and a second nanostructure over the first fin;
forming a first dummy gate and a second dummy gate, wherein the first dummy gate is over the first nanostructure, wherein the second dummy gate is on a first sidewall of the second nanostructure;
forming a dummy nanostructure between the first nanostructure and the first fin;
forming a first spacer between the first nanostructure and the first fin and a second spacer between the second nanostructure and the first fin;
forming a source/drain region over the first fin, wherein the source/drain region is between the first spacer and the second spacer;
removing the first dummy gate and the second dummy gate;
removing the dummy nanostructure;
forming a first gate structure and a second gate structure, wherein the first gate structure is between the first nanostructure and the first fin, wherein the second gate structure is on the first sidewall of the second nanostructure;
removing the second gate structure; and
forming a first isolation structure on the first sidewall of the second nanostructure, wherein the source/drain region is separated from the first isolation structure by the second spacer.

10. The method of claim 9, further comprising forming an isolation region surrounding the first fin, wherein the second dummy gate is over the isolation region adjacent the second nanostructure.

11. The method of claim 10, wherein the first isolation structure is between the isolation region and the first fin.

12. The method of claim 9, further comprising a third spacer on a sidewall of the first isolation structure, wherein the first isolation structure is between the second spacer and the third spacer.

13. The method of claim 9, wherein the source/drain region is separated from the dummy nanostructure by the first spacer.

14. The method of claim 9, further comprising forming a second fin over the substrate adjacent the first fin, wherein the first isolation structure is between the first fin and the second fin.

15. The method of claim 14, wherein the first fin and the second fin have different widths.

16. A device comprising:
a first fin over a substrate, wherein the first fin has a first side and a second side;
a stack of first nanostructures over the first fin;
first inner spacers between ones of the first nanostructures;
a second fin over the substrate, wherein the second fin has a first side and a second side, wherein the first sides of the first fin and the second fin face a first direction, wherein the second sides of the first fin and the second fin face each other;
a stack of second nanostructures over the second fin;
second inner spacers between ones of the second nanostructures; and
an isolation structure extending between the second sides of the first fin and the second fin, wherein the isolation structure separates the stack of first nanostructures from the stack of second nanostructures, wherein the isolation structure has a first side that faces the first direction, wherein the first side of the first fin is a first distance from the first side of the isolation structure, wherein the first side of the second fin is a second distance from the first side of the isolation structure that is different from the first distance.

17. The device of claim 16, wherein a third side of the first fin is coplanar with a third side of the second fin.

18. The device of claim 16, further comprising a stack of third nanostructures over the first fin, wherein the third nanostructures have a length greater than a length of the first nanostructures.

19. The device of claim 16, wherein the isolation structure separates the first inner spacers from the second inner spacers.

20. The device of claim 16, wherein a bottom surface of the isolation structure comprises a plurality of protrusions that extend into the substrate.
